(19) United States
(12) Patent Application Publication
(10) Pub. No.: US 2024/0104136 A1
(43) Pub. Date: Mar. 28, 2024

(54) METHOD AND SYSTEM FOR EFFICIENT PARTITIONING AND CONSTRUCTION OF GRAPHS FOR SCALABLE HIGH-PERFORMANCE SEARCH APPLICATIONS

(71) Applicant: Altera Corporation, San Jose, CA (US)

(72) Inventors: Johan KARLSSON RÖNNBERG, Lulea (SE); Mikael SUNDSTRÖM, Lulea (SE)

(21) Appl. No.: 18/520,358

(22) Filed: Nov. 27, 2023

(51) Int. Cl. G06F 16/901; G06F 16/22; G06F 16/2453; G06F 16/2455

(52) U.S. Cl. CPC G06F 16/9024; G06F 16/2246; G06F 16/24542; G06F 16/24554

(57) ABSTRACT

Methods, apparatus, and systems for efficient partitioning and construction of graphs for scalable high-performance search applications. A method for partitioning a set of ternary keys having one or more wildcards includes analyzing patterns of the set of ternary keys and storing ternary keys with the same pattern in the same subset. The patterns may include uncompressed patterns and compressed patterns. When there are more patterns than a target number of subgraphs, patterns are repeatedly merged until the number of merged patterns matches the target number of subgraphs. Table entries having ternary keys corresponding to the ternary keys in a final set of merged patterns of ternary keys are generated and partitioned into sub-tables, with each sub-table associated with a respective sub-graph. Tables with hundreds of thousands or millions of entries are supported.

### BACKGROUND INFORMATION

Search applications generally employ search keys comprising binary and/or ternary keys. A binary key is a bit string where each bit is either 0 (cleared) or 1 (set) and a ternary key is a bit string where each bit is either 0, 1, or * (wildcard, don't care). A pair of keys match if they are of the same size (length, width), and, for each bit position, the bits in the respective keys are either equal or one of the bits is wildcard.

Under a Ternary Match (TM), a search in a table of ternary keys is performed to find the keys that match a given query key. Typically, the query key is a binary key and a winner among the matching ternary keys is selected based on some tie breaking criteria. Applications for TM include address lookups in routers (e.g., longest prefix match (LPM)), traffic policing- and filtering in gateways and other appliances (e.g., access control lists (ACL)), and deep packet inspection for security applications.

A Ternary Content Addressable Memories (TCAM) is a hardware device that implements TM using a brute force approach wherein ternary keys are stored in registers and the query key is compared to the ternary keys in all registers in parallel to find the matching keys and then designating matching first matching key as winner. TCAMs feature high, deterministic search performance at the cost of extreme power consumption and limited scalability. The largest TCAM devices available in spring of 2023 only scales to a few hundred thousand 480b keys.

Whereas a TCAM provides guaranteed performance independently of the statistical properties of the keys, there are many applications where an algorithmic approach provides sufficient performance with much less overall computing. The extreme example is when there are no wildcards at all in the keys stored in the table. In that case, a simple hashing algorithm yields search performance like TCAM and the amount of computing per search is independent of the table size. Furthermore, a hash table is very simple to scale to higher capacity by just adding more DRAM. TM becomes harder to tackle with an algorithmic approach when there are more wildcards in the ternary keys and when these wildcards are distributed in the keys in a more chaotic fashion.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a graph construction flowchart;

FIG. 2 is a graph constructed from the four keys in TABLE 1;

FIG. 3 shows the top part of the graph consisting of 31 vertices and 32 identical ‘bottom part’ subgraphs illustrated by triangles;

FIG. 4 illustrates one instance of a bottom part subgraph of FIG. 2 consisting of three vertices;

FIG. 5 is a graph supporting partial match search constructed from the keys in TABLE 1;

FIG. 6 is graph resulting from inserting a fifth key in the graph in FIG. 2;

FIG. 6a shows a comparison of the graphs in FIGS. 2 and 6;

FIG. 7 is flowchart showing operations performed during quantum key based partitioning, according to one embodiment;

FIG. 8 is a flow diagram illustrating an example of pattern-based partitioning;

FIG. 9 is a pattern graph with four trees obtained from eight patterns and corresponding subsets by repeatedly merging pattern tree roots;

FIG. 10 is a diagram illustrating the structure of a pattern graph database and how the different constructs are associated;

FIG. 11 is a flow diagram illustrating the process of inserting a new key in the pattern partitioner during batch build, according to one example;

FIG. 12 is a diagram of a computing system on which aspects of the embodiments may be implemented, according to one embodiment;

FIG. 13 is a diagram illustrating an Infrastructure Processing Unit, according to one embodiment;

FIG. 14 is a diagram illustrating a SmartNIC, according to one embodiment;

FIG. 15 is a diagram illustrating a System on Package (SoP) including a CPU coupled to an accelerator complex on which aspects of the embodiments may be implemented;

FIG. 16 is a diagram illustrating further details of the CPU of FIG. 15;

FIG. 17 is a graph comparing the graph partitioning approach and a TCAM for capacity and complexity; and

FIG. 18 is a graph showing power consumption verses a number of keys for the graph partitioning approach and for a TCAM.

### DETAILED DESCRIPTION

Embodiments of methods and systems for efficient partitioning and construction of graphs for scalable high-performance search applications are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

Bits, Keys, and Graphs

A ‘binary bit’ is either ‘false’ or ‘true’, denoted by 0 and 1, respectively, whereas a ‘ternary bit’, can also be ‘wildcard’, or ‘don't care’, denoted by the asterisk operator *. A pair of bits x and y ‘matches’, denoted by x≅y, if x=y, x=*, or y=*. A pair of bits x and y that do not match are said to ‘mismatch’, denoted by x [symbol] y.

Note that the relationship operators ‘=’ and ‘ [symbol] ’ mean ‘equal to’ and ‘not equal to’ according to the standard definition of equality. For example, for bits 0=0, 1=1, *=*, 0≠1, 0≠*, 1≠* etc.

A w-bit ‘key’ X, is an array x₁x₂ . . . x_{w} where each xᵢ is a binary- or ternary bit. A pair of keys X=x₁x₂ . . . x_{w} and Y=y₁y₂ . . . y_{w} ‘matches’, denoted by X≅Y, if xᵢ≅yᵢ for all i=1, 2, . . . , w. A pair of keys X and Y that do not match are said to ‘mismatch’, denoted by X [symbol] Y.

The overall purpose of a graph, in the context of the present invention, is to represent a set of n w-bit keys K={K₁, K₂, . . . , Kₙ} such that, given a query key K the graph can be ‘searched’ to efficiently compute a subset K′ of K, such that, for any key K′∈K′|K≅K′.

TABLE 1

| Key | Data | 12345678 |
|---|---|---|
| K₁ | D₁ | 00101*** |
| K₂ | D₂ | 00*0001* |
| K₃ | D₃ | 1**10011 |
| K₄ | D₄ | ***11*** |

TABLE 1 shows a set of four ternary 8-bit ternary keys K₁, . . . , K₄ with corresponding data D₁, . . . , D₄. The rightmost column shows the individual ternary bits of the keys at the respective bit positions 1 . . . 8 shown in the header. Note that fixed-width font is used to describe bit arrays since it makes it easier to view keys on top of each other and notice similarities and differences. These four keys are easy to distinguish from each other since each key has a unique value in bit positions 4 . . . 5.

Data graphs of nodes and associated data are stored in an associative array. Therefore, addresses or pointers are not required to locate data and code in memory to be executed, e.g., for a next graph node. Instead, a next instruction at a next node in the graph is fetched by starting with a current state ‘Node ID’. Combining it with the results of a ‘computation’ (e.g., a simple calculation, computation test, bit retrieval and concatenating, hash value computation etc.), to create a ‘new search key’, and then using the new search key to access the associative array for a match to the next node, or instruction, in the graph. This process is also termed ‘in-graph computing’.

Since the purpose of the computation mentioned in the previous section is to determine which outgoing edge to follow, we refer to the resulting values and keys from such computations as ‘edge values’ and ‘edge keys’, respectively. Thus, in principle, each node in the graph is constituted by a Node ID and a ‘method’ for edge key retrieval whereas each edge is constituted by a (Node ID, edge value), where Node ID refers to the origin node of the edge, pair which is looked up in the associative memory to obtain the target node reached by traversing the edge.

When the keys stored in the graph are fully specified binary keys, e.g., represented by array of bits where each bit is either 0 or 1, edge key retrieval is straight forward. However, when dealing with ternary binary keys represented by array of bits where each bit is either 0, 1 or *, where * represents ‘wildcard’ or ‘don't care’, edge key retrieval becomes more intricate since inclusion of wildcards bits during edge key retrieval result in several edge values as opposed to a unique edge value. The reason for this is that edge values resulting from all possible assignments of 0 and 1 to wildcard bits must be considered and each such assignment potentially results in a unique edge value. For each such edge value the key must be stored in the subgraph reachable through the edge corresponding to said edge value and the key is thus ‘replicated’ across multiple subgraphs.

For some sets of ternary keys, it is not possible to achieve wildcard free edge key retrieval. It may then be better to partition the set of keys in subsets where wildcard free edge key retrieval can be achieved, or at least inclusion of wildcards bits in edge key retrieval can be minimized, for each subset. This process is referred to as ‘Partitioning’ and the overall purpose is to achieve one graph per subset that can be efficiently represented rather than a single graph that is inefficiently represented.

‘Construction’ refers to the process of building either an entire graph from scratch or re-constructing a sub-graph from a set of keys represented by ternary bit strings. Each key may further be associated with a ‘priority’ and/or a piece of ‘information’.

‘Search’ refers to the process of starting at a given node, which is typically a/the ‘root’ and locating all reachable keys stored in the graph that ‘matches’ a given ‘query key’. There are two kinds of searches and corresponding matches, ‘full match’ and ‘partial match’, and the graph is constructed according to the kind of search to be supported.

Full match means that for each specified bit in the query key the corresponding bit in the matching key stored in the graph is either equal or wildcard. The result from full match search is thus a set of keys guaranteed to match the query key.

Partial match is related to ‘irreducibility’ of sets of keys. A set of keys K={K₁, K₂, . . . }, is said to be ‘irreducible’ if, for any pair of keys Kᵢ and Kⱼ in K, Kᵢ≅Kⱼ. Any set of keys not irreducible is said to be ‘reducible’. To support partial match, it is sufficient to construct the graph until the remaining set of keys is irreducible. The result from partial match is thus a set of keys that ‘may’ match the query key but needs to be further processed to confirm actual matches and remove false positives.

Another dimension of search is how many results that are produced. Full match search can either be ‘full single match’ or ‘full multi match’. Full single match means that the best (according to some tie breaking criteria such as priority etc.) matching key is returned whereas full multi match search means that all matching keys are returned. Hybrids where a limited, according to some threshold, number of best matching keys (again selected according to some tie breaking criteria) are returned as result are also possible. Partial match search is always performed as partial multi match search.

For computer networking applications the query key is often fully specified with no wildcard bits. However, there are also applications where query keys contain one or more wildcard bits.

A directed graph with a single root and wherein each node (except the root) is only reachable from one ‘parent’ node is called a ‘tree’. In a tree, each node reachable from a given parent node is called a ‘child’ of the parent node. Furthermore, the set of nodes including the parent, the grandparent, the great grandparent, and so on until the root, of a node in a tree is the set of ‘ascendants’ of the node and the set of all nodes reachable from the node is the ‘descendants’ of that node. A node without children (no outgoing edges) is referred to as a ‘leaf’.

A directed graph with one or more roots but without ‘cycles’, e.g., without node-edge chains that leads back to the origin, is called a ‘directed acyclic graph’ or ‘DAG’ for short. The terms parent, child, ascendant, and descendant also apply to DAGs noting that a node may have several parents.

While there are applications for more general graphs that contain cycles, the child-parent relationship in such graphs is generally not well defined (since a node may be its own parent/ancestor). In such graphs, a more sophisticated computation of edge keys involving some state may also be required to ensure that searches are terminating.

The definitions of nodes and leaves described herein refer to graphs in general and do not directly translate to in-graph computing in the context of the present disclosure. This is partly due to the actual graphs constructed are not graphs that represent—and operate on keys but rather graphs that represent- and operate on individual bits and selection of bits in keys. An analogy: whereas comparison-based search trees data structures for representing text strings operate on entire strings, ‘Trie’ data structures for representing text strings operate on individual characters (or even individual bits in characters). The toolbox of constructs available in the graph memory engine of the present invention allows for representation- and operation on keys at the bit level, e.g., in the same way as a Trie operates on text strings.

To distinguish between graphs and their constructs, in general, and the corresponding building blocks available in a graph memory engine, nodes and edges in the graph memory engine are referred to as ‘vertices’ (singular: “vertex’) and ‘arcs’ (singular: ‘arc’), respectively.

A ‘label’ is a non-negative integer value.

A ‘map’ is a function that retrieves bit values from a key and compute a ‘label’ from these bit values. If the bit values retrieved from the key include wildcard bits, labels according to all possible 0/1 assignments of wildcard bits are computed thus yielding a set of labels rather than a single label.

A ‘data map’ δ is a function that map a key K to sets of ‘data labels’ δ(K).

An ‘arc map’ is a function that map a key K to sets of ‘arc labels’ α(K).

A ‘vertex’ consists of ‘labeled data’ and ‘labeled arcs’.

‘Labeled data’, or simply ‘data’, is collection of data where each piece of data D_{α} is associated with a ‘data label’ α. Data constitute results of search and is output when visiting the vertex during search if certain criteria (such as matching label) is met.

‘Labeled arcs’, or simply ‘arcs’, is a collection of arcs where each arc A_{α} is associated with an ‘arc label’ α. Arcs constitute the path that binds the graph together and are traversed during search if certain criteria (e.g., matching label) are met.

An ‘arc’ consists of a ‘data map’, an ‘arc map’, and a target ‘vertex’. If the data map and/or arc map of all arcs leading to a particular target vertex are equivalent (e.g., identical) the respective map, or both maps, can be part of the target vertex, yielding a vertex that, in addition to labeled data and labeled arcs, also consists of a data map and an arc map, instead of being part of each of the arcs leading to said target vertex.

Vertices and arcs relate to the previous discussion about nodes, edges and edge key retrieval as follows. An arc label corresponds to an edge key value and the arc map corresponds to edge key retrieval. Moreover, a vertex corresponds to a node and the Node ID, as well, since there is nothing to gain from introducing a special vertex ID. A vertex is combined with an arc label, obtained by applying the arc map of the vertex to the key, to obtain an ‘arc key’, which corresponds to the new search key mentioned above. The arc key is looked up in the associative array to obtain an arc. All arcs leading from a vertex are stored in the associative array with a key that is partly constructed from said vertex and are thus associated with said vertex.

In addition to the above, vertices are also associated with data that is output during search. Such data constitute the result of search and may contain identifiers of which keys are matched, actions to be executed and other information, or may represent a simple index into a table containing arbitrary information, actions, etc. A vertex is combined with a data label, obtained by applying the data map of the vertex to the key, to obtain a ‘data key’. The data key is looked up in the associative array to obtain a piece of data. All pieces of data associated with a vertex are stored in the associative array with a key that is partly constructed from said vertex.

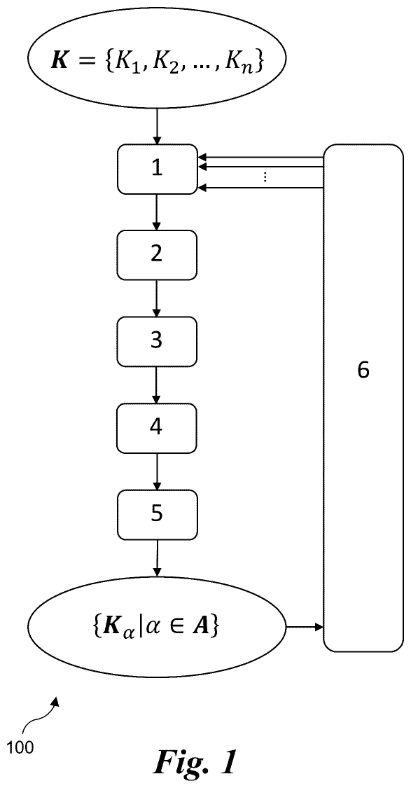

FIG. 1 shows a graph construction flowchart 100. On a high level, construction of a (sub)graph, to represent a set of keys K={K₁, K₂, . . . , K} is a recursive process wherein a vertex and the arc leading to said vertex is constructed at each level in the recursion.

The first operation, in each level in the recursion, is to ‘analyze’ the set of keys K to compute efficient (e.g., ideally optimal) map functions, ‘data map’ and ‘arc map’, respectively.

The second operation, in each level in the recursion, is to compute the set of data labels Dᵢ, for each Kᵢ∈K, followed by computing the set of all data labels D=∪ᵢ₌₁ⁿDᵢ.

The third operation, in each level in the recursion, is to construct the data to be associated with each data label and associate the ‘data label to data’ mapping with the vertex.

The fourth operation, in each level in the recursion, is to compute a set of arc labels Aᵢ, for each Kᵢ∈K, followed by computing the set of all arc labels A=∪ᵢ₌₁ⁿAᵢ.

The fifth operation, in each level in the recursion, is to construct a set of keys K_{α}, for each arc label α∈A, where Kᵢ∈K_{α} if and only if α∈Aᵢ. Note that {K_{α}|α∈A} is typically not a partition of K but it can be.

The sixth operation, in each level in the recursion, is to recursively construct subgraphs associated with each arc label and associate each subgraph, represented by the arc leading to said subgraph, with the corresponding arc label and associate the ‘arc label to arc’ mapping with the vertex. More precisely, for each α∈Aᵢ, an ‘α specified subgraph’, or simply ‘α-subgraph’, is recursively constructed from K_{α} and the arc leading to said subgraph is associated with the arc label α.

As mentioned above, there are different kinds of searches and depending on which kind of search to support the graph can be constructed differently.

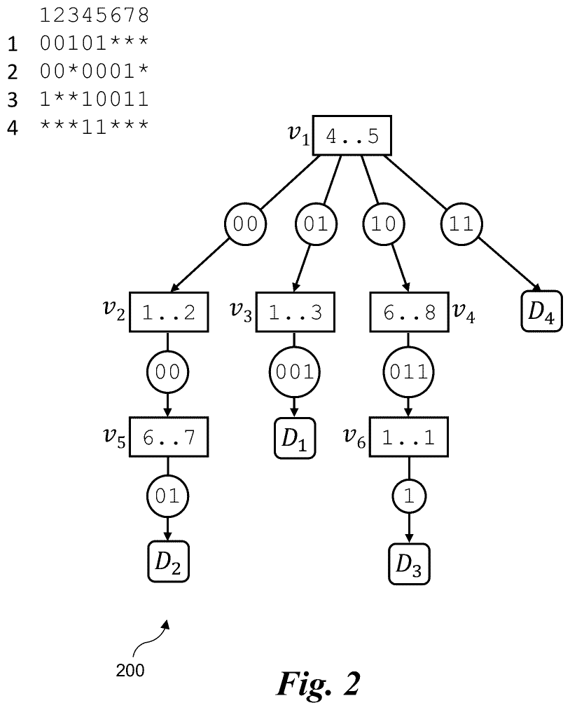

FIG. 2 shows a graph constructed from the four keys in TABLE 1. Vertices consist of data- and arc maps and are shown as rectangles with start bit position and end bit position of retrieval. Data and arc labels are shown as circles containing the arc label in base two, and output data are shown in rectangles with rounded corners containing the respective piece of data.

The graph of FIG. 2 supports full single match search as well as full multiple match search. The graph consists of 6 vertices v₁, . . . , v₆, where v₁ is the root vertex. The arc map of v₁ retrieves bits 4 . . . 5 of the query key yielding four different arc labels 0=00_{b}, 1=01_{b}, 2=10_{b}, and 3=11_{b}. The four keys all have different values in bits 4 . . . 5 and, as a result, the choice of arc map in the root vertex partitions the input without causing any replication. Arc label 00_{b} is associated with an arc leading to vertex v₂ where the only possible matching key is K₂ with associated data D₂. In v₂ the next pair of specified bits 1 . . . 2 in K₂ are checked and the arc label 00_{b}, which is the only available arc label, leads to vertex v₅. Note that v₅ does not have any outgoing arcs. In v₅ the remaining two bits at location/position 6 . . . 7 are checked. If bits 6 . . . 7 matches the data label 00_{b} in vertex v₅, all specified bits of the key have been matched and the data D₂ associated with the data label 00_{b} is output. Similarly, arc labels 01_{b} and 10_{b} of the root vertex leads to subgraphs where the remaining bits of keys K₂ and K₃ are matched, respectively. Since only bits 4 . . . 5 of K₄ are specified, the root vertex has a data label 11_{b} with associated output data D₄ that is output as K₄ is matched.

TABLE 2

| Associative Memory Input | | | Associative Memory Output | | | |
|---|---|---|---|---|---|---|
| Vertex | Data label | Arc label | Data | Vertex | Data Map | Arc Map |
| | | | | v₁ | 4 . . . 5 | 4 . . . 5 |
| v₁ | | 00_{b} | | v₂ | | 1 . . . 2 |
| v₁ | | 01_{b} | | v₃ | 1 . . . 3 | |
| v₁ | | 10_{b} | | v₄ | | 6 . . . 8 |
| v₁ | 11_{b} | | D₄ | | | |
| v₂ | | 00_{b} | | v₅ | 6 . . . 7 | |
| v₃ | 001_{b} | | D₁ | | | |
| v₄ | | 011_{b} | | v₆ | 1 . . . 1 | |
| v₅ | 01_{b} | | D₂ | | | |
| v₆ | 1_{b} | | D₃ | | | |

The content of the associative memory for the graph in FIG. 2 is shown in TABLE 2. Associative memory input (v, δ, α) is represented by a source vertex v, a data label δ, and an arc label α, whereas associative memory output (D, v, δ, α) is represented by a piece of data D, a destination vertex v, a data map δ and an arc map α. Note that there is no key (Associative Memory Input) for the root vertex as it is represented by the associative memory output (−, v₁, 4 . . . 5, 4 . . . 5), where ‘−’ denotes omitted input/output.

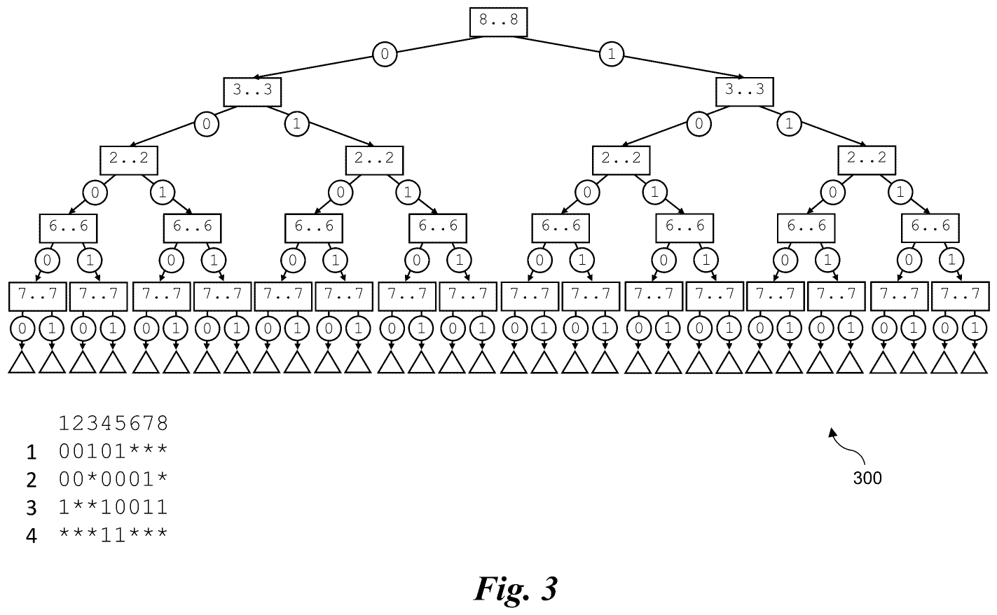

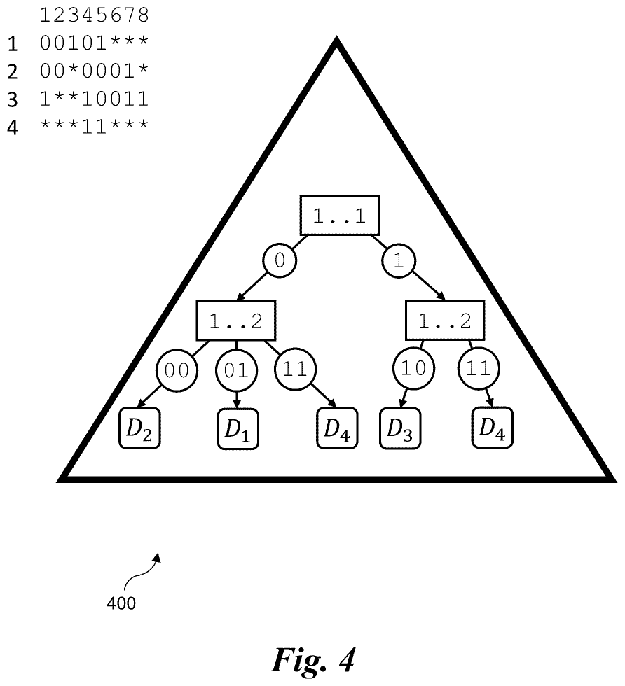

In the brief description of recursive graph construction above, the purpose of one operation at each level in the recursion is computation of efficient maps, in particular arc maps. FIGS. 3 and 4 shows a graph, supporting full single match search and full multiple match search constructed, from the keys in TABLE 1 using the ‘worst possible’ arc map functions at each level. FIG. 3 shows the top part of the graph consisting of 31 vertices and 32 identical ‘bottom part’ subgraphs illustrated by triangles. FIG. 4 illustrates one instance of a bottom part subgraph consisting of three vertices. In total, the graph constructed using inefficient arc maps consists of 127 vertices to be compared with the graph constructed using efficient arc maps which consists of only six vertices. Furthermore, the depth, measured in maximum number of arcs traversed to reach from the root vertex to a terminating vertex, is six in the graph constructed using inefficient arc maps and two in the graph constructed using efficient arc maps (bottom arrow is not counted as an arc since it refers to data). This example and comparison clearly show the importance of computing efficient arc map functions to achieve efficient graph representation.

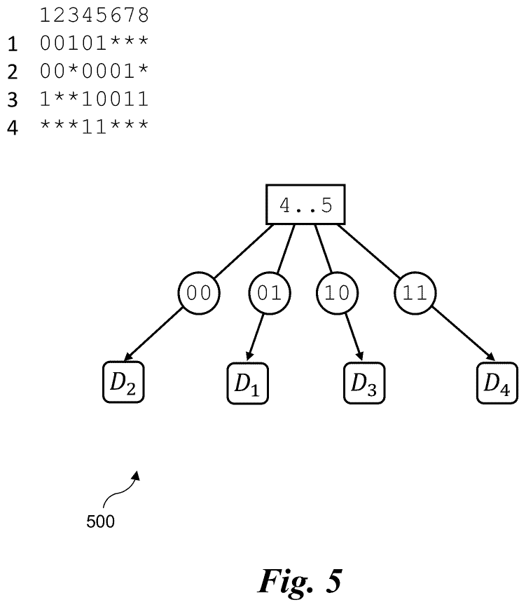

FIG. 5 shows a graph supporting partial match search constructed from the keys in TABLE 1. Note that since only partial match search is supported not all bits of the keys are matched. It is sufficient to match enough bits to be able to discriminate keys from each other and obtain irreducible subsets (a set of one key is obviously irreducible).

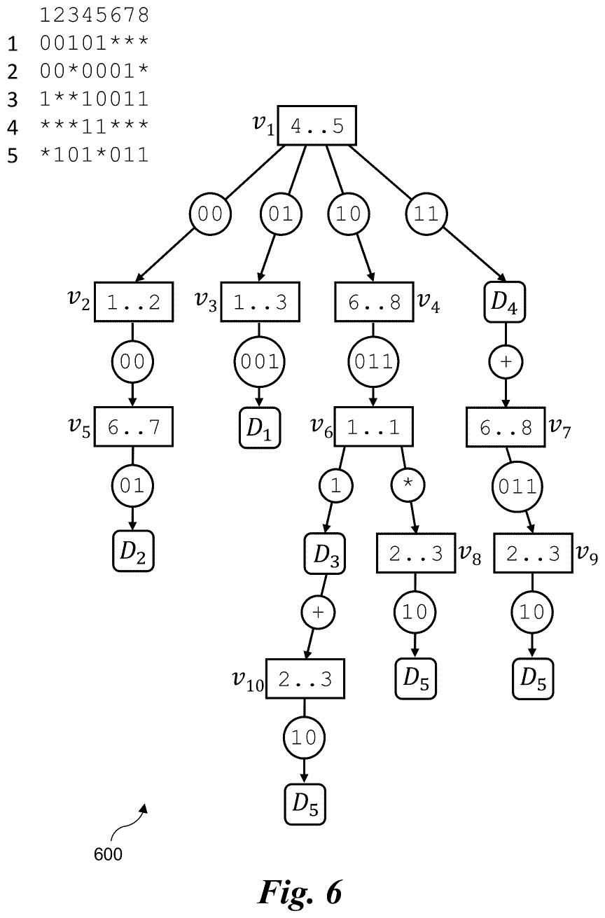

FIG. 6 shows a graph 600 resulting from inserting a fifth key in graph 200 in FIG. 2, while FIG. 6a shows a comparison between graphs 200 and 600. This results in new vertexes v₇, v₈, v₉, and v₁₀ being added, as follows. Vertex v₆ retrieves bits 1 . . . 1, as before, which now yields two arc labels 1 and * rather than just a single arc label 1. Arc label 1 leads to data D₃, as before, but further leads to vertex v₁₀. The arc map of v₁₀ retrieves bits 2 . . . 3, which has an arc label 10_{b}, where all specified bits of the key K₅ have been matched resulting in a first instance of data D₅. Arc label * from vertex v₆ leads to vertex v₈. The arc map of v₈ retrieves bits 2 . . . 3 of the query key yielding arc label 10b, where, as above, all specified bits of the key K₅ have been matched resulting in a second instance of data D₅. Vertex v₇ is added to data D₄, and has an arc map that retrieves bits 6 . . . 8 of the query key yielding arc label 011_{b}, which yields vertex v₉. The arc map of v₉ retrieves bits 2 . . . 3 of the query key yielding arc label 10_{b}, where all specified bits of the key have been matched for a third time and a third instance of data D₅ associated with the data label 10_{b} is output.

This concludes the high-level description of graph memory engine graph constructs and construction covering only specified arcs and corresponding subgraphs. There are also ‘unspecified’ and ‘mandatory’ arcs and subgraphs, respectively, and these are described in detail below. In what follows, partitioning of input set into subsets to simplify/enable more efficient construction of data- and arc maps as well as a multitude of methods to construct maps is described in more detail.

### Partitioning

The purpose of partitioning is primarily to obtain a partition of keys such that an efficient graph can be constructed for each subset. There are two aspects of efficiency to consider, ‘space’ and ‘time’. ‘Space efficiency’ aims at minimizing the number of vertices and arcs required to represent the graph whereas ‘time efficiency’ aims at minimizing the number of vertices that are visited during search. Time efficiency optimization targets include ‘worst case time efficiency’ considering the maximum number of vertices visited during search for any wildcard free query key or any query key with a limited number of wildcards (a query key where all bits are wildcards matches all keys stored in the graph and the entire graph is thus traversed).

If all keys are fully specified, it is straight forward to construct efficient arc maps. Each key yields only a single arc label, in each vertex, and thus {K_{α}|α∈A} becomes a partition of K, in said vertex. This also implies that each key is only stored in one subgraph of any given vertex.

However, if keys contain wildcards, it may be impossible to construct an arc map such {Kα|α∈A} is a partition of K in each vertex. If, for a given vertex, {Kα|α∈A} is not a partition, the ‘replication’ in said vertex equals (Σ_{α∈A}|K_{α}|)−|K|, where |K| denotes the cardinality of K (number of elements in K).

Replication is particularly high for irreducible sets of keys and may cause severe space explosions if not managed adequately. Note also that replication not only impacts space efficiency since additional vertices also yield a deeper graph and thus reduced time efficiency.

Overall ‘replication’ is defined as the sum of replications across all individual vertices.

Having defined replication, the purpose of partitioning can be more clearly stated as a method to partition the input key set in subsets such that a graph with minimum replication can be constructed for each subset.

It is straight forward to minimize replication if there is no limit on the number of subsets in the partition produced by partitioning. In particular, n keys can be partitioned into n subsets with a single key in each subset. However, it is also important to minimize, or limit, the number of subsets/graphs. The reason for this is that all graphs must be searched and there is typically a limited capability of how many graphs that can be searched in parallel.

Finding the ‘optimal’ way of partitioning would require testing all different ways of partitioning the set of keys and for each such partitioning finding the optimal way of constructing a graph for each subset. In turn, this would require testing all possible methods of edge key retrieval at each level recursively and so on. Clearly, this is computationally feasible only for ridiculously small sets of keys and key sizes (the length of bit arrays representing the keys) and cannot be achieved at scale using currently available hardware (it would likely require a quantum computer or similar).

### Quantum Key Based Partitioning

The simplest form of Partitioning is performed using a heuristic approach where the set of keys are first pre-processed by sorting them according to a ‘niceness’ (versus ‘badness’) criteria or measure. There are several possible niceness measures that can be applied, and a key is generally considered nice if it is easy distinguish from the other keys in the graph.

In one embodiment, niceness is quantified as number of specified bits where a key with more specified bits is considered nicer than a key with fewer specified bits. In an alternative embodiment, niceness is quantified as the ratio between number of unspecified bits and number of specified bits where a key with lower ratio (zero being the ideal ratio) is considered nicer than a key with a larger ratio.

In some embodiments a ‘quantum key’ Q=q₁q₂ . . . q_{w}, representing a set of n=|Q| keys, is used to compute niceness of an individual key with respect to a set of n keys. Each qᵢ=(nᵢ₀, nᵢ₁, n_{i*}), of the quantum key, represent three metrics where nᵢ₀ is the number of keys, where bit i is 0, nᵢ₁ is the number of keys where bit i is 1, and n_{i*} is the number of keys where bit i is wildcard. Niceness of a key K=k₁k₂ . . . k_{w}, with respect to such a set of n keys, represented by the quantum key Q, is then quantified by the ‘distance’ (small distance is nicer than large distance) between the key K and the quantum key Q which is computed as follows.

Starting with zₙ=z_{d}=cₙ=c_{d}=0 and wₙ=w_{d}=1, subtracting 1 from n if the key is in the set of n keys, then for each i=1, 2, . . . , w: increase z_{d} by nᵢ₁/n if kᵢ equals 0, increase z_{d} by nᵢ₀/n if kᵢ equals 1, or increase zₙ by (nᵢ₀+ε)·(nᵢ₁+ε)/n², where ε is a small number larger than zero, if kᵢ equals *. Then assigning z_{d}←max(z_{d}−c_{d}, 0)·w_{d} and zₙ←max(zₙ−cₙ, 0)·wₙ. The final distance is then computed as follows: if z_{d}=zₙ=0 the distance is 0, if z_{d}=0 the distance is ∞, and otherwise the distance is z_{d}/zₙ.

A person skilled in the art can generalize the abovementioned embodiments using other values of the threshold- and weight parameters cₙ, c_{d}, wₙ and w_{d} to achieve alternative embodiments with slightly different characteristics as well as generalize any quantum key based distance computation embodiment with deeper level quantum keys as well as combining different niceness measurement methods into hybrids methods in the spirit of the present disclosure.

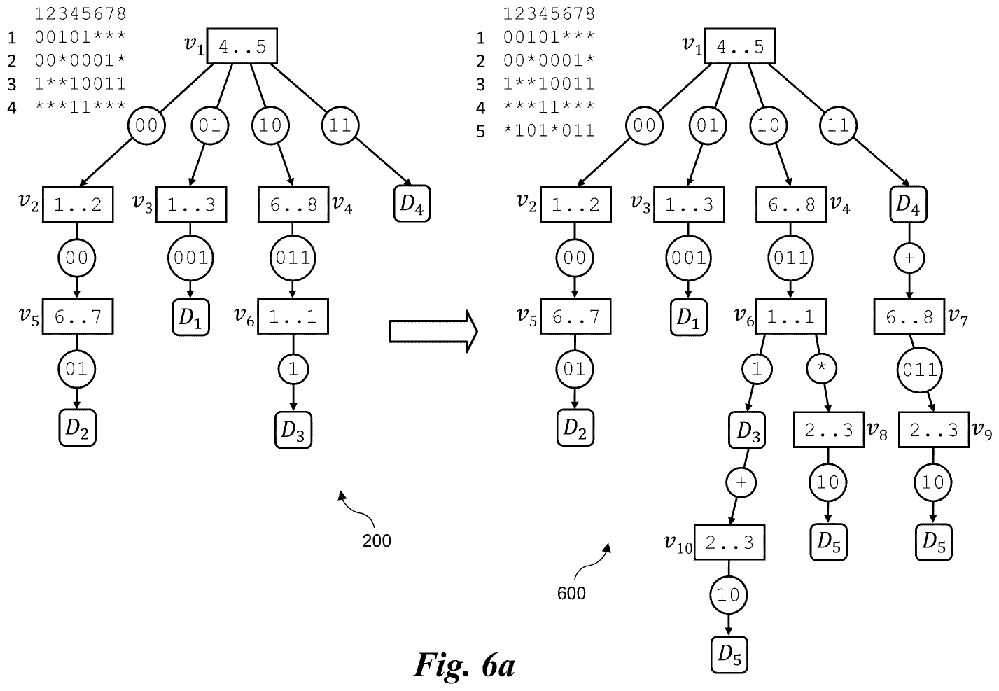

FIG. 7 is a flowchart 700 showing operations performed during quantum key based partitioning, according to one embodiment. After performing the initial sorting (1) of keys according to niceness, partitioning commences by processing the keys in sorted order and inserting them in the subset with the heuristically best fit. There are s subsets C₁, C₂ . . . , Cₛ available and initially all subsets are empty (Cᵢ is used here to denote a subset of keys produced by partitioning to avoid confusing it with K_{α} which denotes a set of keys associated with an arc label during vertex construction).

After performing the initial sorting of keys, partitioning commences by processing the keys in sorted order and inserting them in the subset with the heuristically best fit. There are s subsets C₁, C₂ . . . , Cₛ available and initially all subsets are empty (Cᵢ is used here to denote a subset of keys produced by partitioning to avoid confusing it with K_{α} which denotes a set of keys associated with an arc label during vertex construction).

To allow for tweaking of partitioning behavior two non-negative distance thresholds called ‘match threshold’ denoted by m and ‘dirty threshold’ denoted by \hat{d} are used. If \hat{d}>0 the last subset Cₛ is reserved for the worst keys unofficially referred to as the ‘dirty dozen’. Throughout the partitioning, quantum keys Q₁, Q₂, . . . , Qₛ are maintained for each respective subset and updated immediately when a key is added to the respective subset. Starting with the nicest key and progressing throughout less and less nice keys, according to the initial sorting, the best fitting subset for each key is selected as follows:

The first key is inserted in the first subset C₁ (2). The following keys are processed as follows (3). If there are non-empty subsets and the shortest distance between the key and the quantum key Qᵢ of a non-empty subset Cᵢ is less than or equal to \hat{m}, the key is added to Cᵢ (4), if there are non-empty subsets, \hat{d}>0, and the shortest distance between the key and the quantum key Qᵢ of a non-empty subset Cᵢ is less than or equal to \hat{d}, the key is added to Cₛ(5), if there are non-empty subsets (excluding Cₛ if \hat{d}>0) and the shortest distance between the key and the quantum key Qᵢ of a non-empty subset Cᵢ is larger than \hat{m}, the key is added to the first empty subset (6), otherwise if there are no empty subsets (excluding Cₛ if \hat{d}>0) the key is added to the subset with the smallest distance quantum key (7). When all keys have been processed the resulting partition is available (8).

The default values of \hat{m} and \hat{d} are 0.05 and 1.0, respectively. These have been carefully selected to provide efficient partitioning for a wide range of distributions of up to 480-bit keys and 16 subsets.

A person skilled in the art may perform experimentation with different number of subsets, observe partitioning behavior for different input sets and select other values of partitioning parameters, and different partitioning parameters for sorting and partitioning, as well as additional thresholds and parameters in the spirit of the present disclosure.

### Pattern Based Partitioning

The ‘pattern’ P=p₁p₂ . . . p_{w} of a key K=k₁k₂ . . . k_{w} is a binary bit string where pᵢ=0 if kᵢ=* and pᵢ=1 if kᵢ=0 or kᵢ=1. When using quantum key based partitioning, keys with the same pattern may end up in different subsets of the partition. The core idea behind pattern-based partitioning is to assign keys with the same pattern in the same subset of the partition and, once sufficiently many keys have been analyzed and partitioned, assign additional keys to subsets merely based on their pattern.

If the target number of subsets of the partition is less than or equal to the number of different patterns, the keys of each subset will have the same pattern. Since discriminating bits, selected during graph construction, are only selected among specified (e.g., with value 0 or 1) bits, no replication of keys may occur in a graph constructed from such a subset. In this case, pattern-based partitioning is trivial.

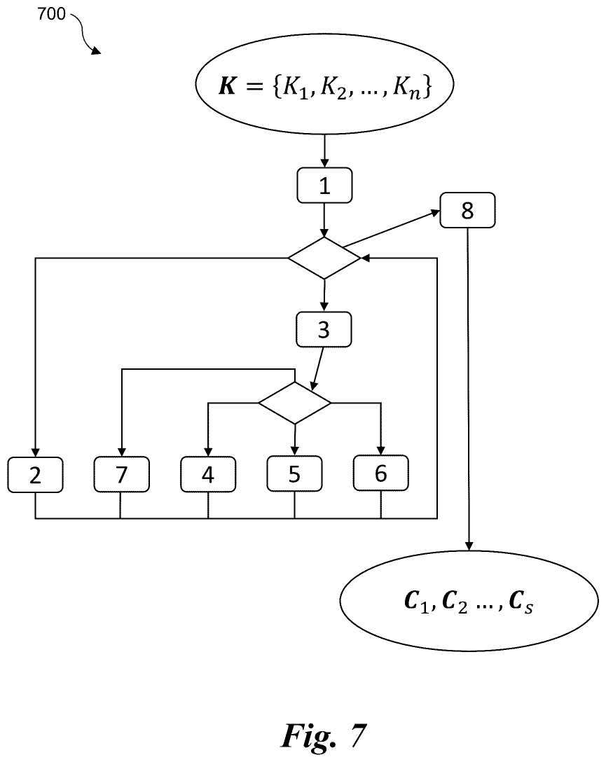

In the simplest pattern-based partitioning embodiment, illustrated in flow diagram 800 in FIG. 8, partitioning is performed when all keys are available, and no new keys arrive (are inserted) after the partitioning is performed.

Consider a set of keys K={K₁, K₂, . . . , K} and the corresponding set of patterns P={P₁, P₂, . . . , Pₘ}, n≥m. Further assume that there are no restrictions on the sizes of individual subsets, or groups of subsets, in the resulting partition.

The first operation (1) in partitioning the set K of keys into t≤m subsets is to create a partition C¹={C₁¹, C₂¹, . . . , Cₘ¹}, where Cᵢ¹ consists of the keys with pattern Pᵢ. For each such subset Cᵢ¹ a quantum key Qᵢ¹ is created from the rules.

The second operation (2) in partitioning the set K of keys into t≤m subsets is to select a pair of subsets Cᵢ¹ and C₁^{j}, i<j, and merge these to obtain Cₘ₋₁². The remaining C₁¹, . . . , Cᵢ₋₁¹, Cᵢ₊₁¹, Cⱼ₋₁¹, . . . , Cⱼ₊₁¹, . . . , Cₘ¹, becomes C₁², C₂², . . . , Cₘ₋₂². As shown by the loop back to operation 2 from decision block 802, this ‘reduction’ process is repeated until the remaining number of subsets is less than or equal to the target number of subsets t.

To determine which subsets to merge, a merge cost is computed from each pair of quantum keys and the pair with the lowest merge cost is selected. In some embodiments, the merge cost is computed from a pair of quantum keys Q′ and Q″ as follows: First, pair of counters disc and repl are initialized to zero. For each bit position i in the quantum keys Q′ and Q″, respectively, q′ᵢ=(n′ᵢ₀, n′ᵢ₁, n′_{i*}) and q″ᵢ=(n″ᵢ₀, n″ᵢ₁ n″_{i*}), respectively, are extracted followed by computing nᵢ₀=n′ᵢ₀+n″ᵢ₁, nᵢ₁=n′ᵢ₁+n″ᵢ₁, and n_{i*}=n′_{i*}+n″_{i*}. If n_{i*}=0 and nᵢ₀+nᵢ₁>0, disc is increased by one before moving on to the next bit position. Otherwise, if nᵢ₀+nᵢ₁>0 and n_{i*}>0, repl is increased by one before moving on to the next bit position. When all bit positions have been processed, the final merge cost is (|Q′|+|Q″|)/disc, if disc>0, and repl·|Q′|·|Q″|, otherwise. A person skilled in the art can generalize the method of merge cost computation by including additional statistics about the sets of patterns and corresponding keys to be merged in the computation as well as tweak the parameters included in the computation to optimize the merge cost computation for additional applications.

The repeated mergers of patterns and subsets, until sufficiently few remains, yields trees of subsets constructed bottom up starting with the leaves and ending with the root nodes. A merge operation performed during reduction effectively merges the roots of a pair of trees to create a new tree and thus reduce the number of trees by one.

To distinguish these trees and constructs from other graph/sub-graph/tree constructs, these trees and their constructs are referred to as ‘pattern trees’, ‘pattern roots’, ‘pattern nodes’, and ‘pattern leaves’, respectively.

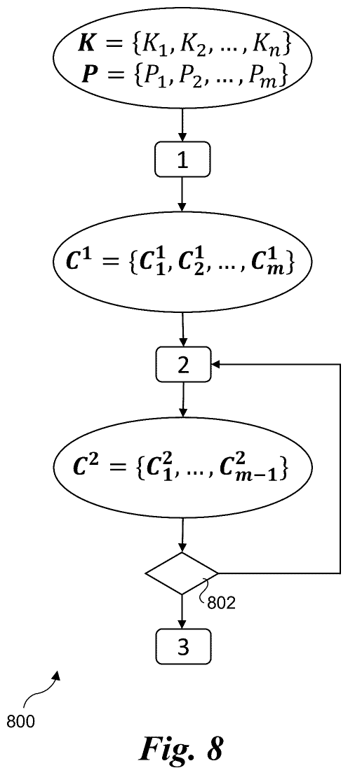

FIG. 9 shows a pattern graph 900 with four trees obtained from eight patterns and corresponding subsets by repeatedly merging pattern tree roots in four operations: C₁¹+C₁²→C₇², C₆¹+C₆³→C₇², C₅¹+C₈¹→C₅⁴, and C₃¹+C₇²→C₄⁵. Note that the presented pair-based numbering of subsets throughout the different operations is merely an example. Other numberings such as single numberings where a new subset is assigned the next free number, e.g. C₁+C₂→C₉ instead of C₁¹+C₂¹→C₇², are also possible.

A pattern leaf is associated with a subset of keys with the same pattern. If there are not any limitations imposed on the number of keys that can be stored in one subset of the final partition, there will be exactly one pattern leaf for each pattern, but if there are limitations, a set of keys with the same pattern may be further partitioned and each resulting subset will be associated with a separate pattern leaf.

After the first operation during pattern-based partitioning, yielding C¹={C₁¹, C₂¹, . . . , Cₘ¹}, each Cᵢ¹ is associated with a pattern leaf which is also a pattern root. In each operation during reduction, a pair of pattern roots are selected (based on the quantum key merge cost outlined above) and merged this reducing the number of pattern roots by one.

To keep track of subsets and patterns a database of patterns is maintained. Any dictionary or key-value store database, such as a hash table, can be used to represent such a database since patterns are binary strings. The key in the pattern table is the pattern (bit string) and the data associated with the key is a reference to a ‘pattern head’. In the simplest pattern based partitioning embodiment, a pattern head contains only a single ‘pattern tail’ (or a reference to a pattern tail).

A pattern tail contains a reference to its pattern head, a reference to a pattern leaf containing all (or a subset of) the keys with the same pattern as the pattern associated with the pattern head, a database of keys stored in the subset associated with the pattern leaf, and a reference to the pattern root of the tree containing the pattern leaf. Note that the pattern root reference, stored in the leaf, is identical to the pattern leaf reference if the pattern leaf has not been involved in a merger.

To keep track of the pattern leaves associated with keys that are inserted, the pattern partitioner maintains a database where a reference to the pattern leaf containing the subset containing each inserted key can be looked up using the key as key. As with patterns, any dictionary or key-value store database, such as a hash table, can be used also to represent the database for mapping (inserted) keys to pattern leaves.

In some embodiments the number of keys that can be stored in a single graph is limited and in some embodiments groups of graphs share resources such that the total number of keys in the graphs of the same group is limited. In either case, the number of keys in a single origin subset of a common pattern may be too large to store in a single graph.

In such an embodiment, keys with the same pattern may be stored in several subsets and each such subset will then be associated with a separate pattern tail. Note that, in such a case, all pattern tails associated (via pattern leaves) with subsets of keys with the same pattern shares a single pattern head. That is, there is at most one pattern head per pattern.

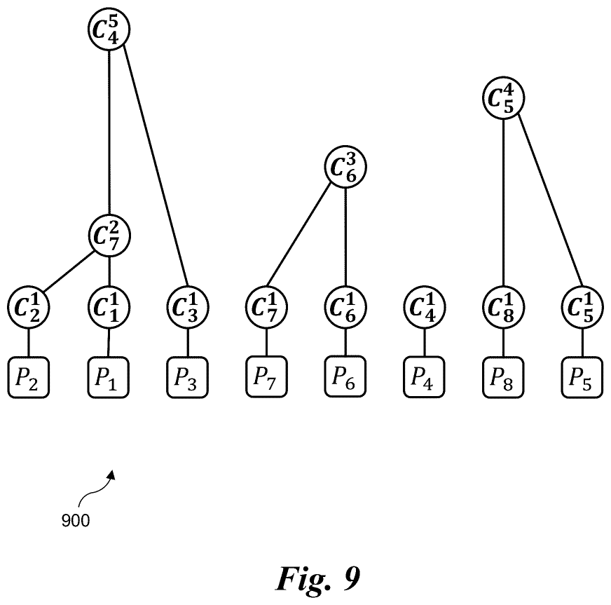

FIG. 10 shows the structure of a pattern graph database 1000 and how the different constructs are associated. For each pattern P there is a corresponding head H. The pattern construct includes a reference to the head construct and vice versa as illustrated by the double arrow between P and H. In the general case, e.g., when there is a limit that prevents all keys with the same pattern to be stored in one subset, there are several subsets of keys C and for each subset there is a corresponding tail T. Similar to patterns and heads, each subset construct includes a reference to the corresponding tail and vice versa. Tails are organized in a single linked list where each tail construct includes a reference to the next tail construct in the list. Furthermore, each tail construct includes a reference to the head construct and the head construct includes a reference to the first tail construct in the list. Each key in each subset is associated with the tail of the corresponding subset (not explicitly shown in the figure). In this way, keys, subsets, tails, heads, and patterns are directly or indirectly associated thus simplifying management and distribution of keys in the respective subgraphs.

In an alternative embodiment, existing keys are deleted and new keys, with a known pattern, are inserted on-the-fly after the initial partitioning is completed provided that no new origin subsets need to be created during insertion. In such an embodiment, the pattern of the new key is first constructed and looked up in the pattern database to determine if it is a known pattern or not. If the pattern is known, e.g., a head associated with the pattern exists, and there are no limits on number of keys in sub-graphs, the key is simply inserted into the subset associated with a (or the) pattern tail associated with the pattern head.

If there are limits, one of the pattern tails associated with the pattern head is selected, while taking said limits into account, and the key is inserted in the subset associated with said pattern tail followed by updating the quantum key of the pattern leaf, associated with the pattern tail, with the new key. If no subset has room for the key, the insertion fails.

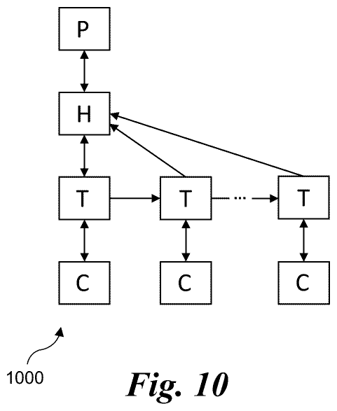

FIG. 11 shows a flow diagram 1000 illustrating the process of inserting a new key in the pattern partitioner during batch build, e.g., search graphs are built after partitioning is completed. Insertion starts by constructing the key's pattern (1) and looking up the pattern in the pattern database. If the pattern is not present in the pattern database, e.g., it is a new pattern, a new pattern-head and corresponding single tail-subset structure is constructed (see FIG. 10 above) where the new key becomes the single element in the subset followed by inserting the pattern construct in the pattern database. If the pattern is known, and space is available in one of the subsets associated with the pattern, one of these is selected, while taking load balancing and possibly other circumstances into account, and the key is inserted into the selected subset. Otherwise, the pattern is known but all subsets are full, a new tail is created and appended at the end of the tail list, and the new key becomes the single element of the subset associated with the tail. Though not explicitly mentioned, each key is associated with the tail corresponding to the subset where it is inserted after insertion. Furthermore, the corresponding quantum key of the subset, stored in the corresponding tail construct, is updated with the new key. Deletion of a key is always successful.

In an alternative embodiment, keys with unknown patterns or keys, which for other reasons require additional subsets, are inserted on the fly. In one possible such embodiment, all pre-existing keys are deleted and then inserted when a single new key is inserted. This is called ‘batch partitioning’ and results in all sub-graphs/trees built during previous construction are scrapped and new sub-graphs/trees are built from scratch. In another possible such embodiment, new keys inserted may introduce additional patterns or otherwise requires that additional origin subsets are created due to limitations on graph sizes as mentioned above.

In such embodiments it may be required to first ‘expand’ the number of subsets by repeatedly ‘unmerging’ previously merged pattern trees. This is achieved by selecting the pattern root with the largest merge cost and unmerge (or split) it. Expansion, by repeatedly unmerging pattern roots with the largest merging cost, continues until it is possible to perform reduction while satisfying any limitations on number of rules per sub-graph or and/or groups of sub-graphs.

Between insertions of new keys, each pattern root is associated with a sub-graph which is constructed according to the description in the GRAPH CONSTRUCTION section below. When performing an expansion and reduction cycle, keys are moved between sub-graphs. Such moves between sub-graphs consider the size of unmerged subsets such that the smaller subset resulting from splitting a subset is moved and the larger stays. Thus, the total number of moves is minimized.

In some cases, the number of different patterns makes it hard to perform reduction efficiently. For example, when the number of patterns is in the same order of magnitude as the number of keys. The present invention addresses this problem by combining ‘pattern compression’ and ‘heap-based reduction’. Pattern compression refers to a method of reducing the number of patterns by using fewer bits to represent the pattern than the number of bits in the keys. The simplest pattern compression, employed by some embodiments, is ‘quantization-based pattern compression’. Starting with the ‘full pattern’ of a key, e.g. the pattern as defined above where the size of the pattern is the same as the size of the key, chunks of 2^{quant} consecutive bits are analyzed and if all bits are set, a corresponding set bit in the compressed pattern is created. If any of the q bits are cleared, the corresponding compressed bit is cleared. Assigning quant=1, 2, 3 yield a compression of two, four, and eight respectively, the latter resulting in a 60-bit pattern for a 480-bit key.

An alternative compression scheme ‘quantization-based pattern compression with threshold’, compares the number of set bits in the chunk (as mentioned above) with a threshold and sets the bit in the compressed pattern if the number of set bits in the full pattern exceeds the threshold.

A person skilled in the art can generalize the above pattern compression schemes to obtain additional embodiments that employs alternative compression methods, including but not limited to, compression with chunk sizes other than powers of two, variable sized chunks, and variable thresholds.

Heap based reduction is a method to speed up the repeated selection of which subsets to merge and thus improve the speed of the entire reduction process. When performing naïve reduction, the merge costs of all pairs of merge candidates are computed in each operation and the pair with the smallest merge cost is merged. This means that for m subsets, m·(m−1) merge costs are computed in the first operation, (m−1)·(m−2) merge costs are computed the second operation, and so on, yielding a total number of computed merge costs proportional to m³. Therefore, the naïve method is feasible only for relatively small number of patterns. Heap based reduction starts by computing all m·(m−1) merge costs and inserting the subset pair in a priority queue with the merge cost as priority. A simple embodiment uses a Heap as priority queue, but other priority queues are also possible to use. Reduction is performed by repeatedly extracting the pair with the smallest merge cost from the priority queue until a pair where both subsets qualify for merging is obtained. Qualified means that none of the subsets have been involved in a previous merger—they are both roots of their respective pattern trees. The obtained subsets are then merged and all pairs, currently present in the priority queue, that contain any of the merged subsets become disqualified. Before moving on to the next reduction operation, the merge cost of merging the new subset, resulting from the merger, with each of the remaining qualified subset is computed and the pair is inserted in the priority queue with the computed merge cost as priority.

### Graph Construction

There are several different kinds of arcs and corresponding arc labels. A ‘specified arc’ is an arc corresponding to a ‘specified arc label’. All arcs and arc labels described above are specified arcs. An arc A_{α} with the label α is referred to a α-arc and the corresponding subgraph, reached by traversing the arc A_{α}, is referred to as an α-subgraph.

An ‘unspecified arc’, or ‘*-arc’, is an arc corresponding to all ‘unspecified arc labels’, that is all arc labels that (for whatever reason) are not included in the set of specified arc labels. It is possible, during construction of a vertex, to only consider a subset of A as specified arc labels and treat the rest as unspecified arc labels. Other examples of unspecified arc labels are during search when the arc label, obtained from computing the arc map of the query key in a vertex, does not match any of the specified arc labels in the vertex. The subgraph reached via an *-arc is referred to as ‘unspecified subgraph’ or ‘*-subgraph’.

A ‘mandatory arc’, or ‘+-arc, is an arc without an arc label that must always be traversed during search independently of whether the arc label of the query key is equal to a specified- or unspecified arc label or not. Note that search will typically branch out across multiple paths at vertices with mandatory arcs even if the query key is fully specified. The subgraph reached via a +-arc is referred to as ‘mandatory subgraph’ or ‘+-subgraph’.

As with arcs, there are also different kinds of data. A piece of specified data is a piece of data corresponding to a ‘specified data label’. A piece of data D_{α} associated with data label α is referred to as α-data and is output, during search, when visiting the vertex if the data label α is computed from the query key. A piece of ‘unspecified data’, denoted by D_{*}, is a piece of data that is output, during search, if the data label computed from the key is not equal to any of the specified data labels of the vertex. Unspecified data may—or may not be present in the vertex. A piece of ‘mandatory data’, denoted by D₊, is a piece of data that is always output, during search, when visiting the vertex containing mandatory data. Mandatory data may- or may not be present in a vertex.

A vertex with at least two specified arc labels is called a ‘branching vertex’ and a vertex with less than two specified arc labels is called a ‘non-branching vertex’.

Before describing the construction of vertices in more detail the different scenarios of terminating subgraphs are next described.

There are three different variants of terminating a graph depending on which kind of search to support. To support ‘full multi match’ search, chains of all possibly matching vertices that represent all non-wildcard bits of individual keys must be created to ensure that all specified keys are matched before concluding that the keys match (and returning the data/information associated recorded in vertices) whereas for ‘partial match’ search it is sufficient terminate the graph when the set of keys to construct the subgraph from is irreducible.

Construction of a graph supporting full single- or multi match search from a single key K associated with output data D is achieved as follows. Find the longest sequence of specified bits in K and extract as label λ. Clone K to K′ and set all the extracted bits in K′ to wildcard. If the entire K′ is wildcard, complete the construction by storing (λ, D) as key-data pair, e.g., D_{λ}=D, in the current vertex. Otherwise, construct a λ-subgraph A_{λ} from K′ and complete the construction by storing (λ, A_{λ}) as key-arc pair in the current vertex.

Construction of a graph supporting full single match search from an irreducible set of keys K is achieved by selecting one key K (e.g., the highest priority key if the keys have priority) and construct a subgraph root vertex as if it is a single key, with the following modification. Instead of recursively constructing an λ-subgraph from K, an λ-subgraph A_{λ} is constructed from K′, which is constructed by cloning each key in K and setting all extracted bits in the key to wildcard in the same way K′ is constructed from K. Furthermore, a *-subgraph is constructed from K′\{K′}.

Construction of a graph, where each vertex can hold a single piece of data, supporting partial match search from an irreducible set of keys K is achieved by selecting one key K associated with output data D, as in the single match case, and store D as mandatory data D₊=D in the vertex. This is followed by recursively constructing a *-subgraph from K\{K}.

Construction of a graph, where each vertex can hold either a restricted- or an arbitrary number of pieces of data, supporting partial match search from an irreducible set of keys K with associated pieces of data D is achieved by simply storing D as mandatory data D₊=D in the vertex.

Consider construction of a vertex from a set of keys K, and focus on the selection of specified arc labels S, and unspecified arc labels U, from the set of arc labels A (note that {S, U} is a partition of A).

One approach is to select S=A. This means that all arc labels are considered specified arc labels and only those not obtained from any of the keys are considered unspecified. This approach works quite well if there are none, or at least very few, wildcards among the bits retrieved during arc map computation. Keys where many bits are retrieved during arc map computation are likely to yield many arc labels and are thus heavily replicated. An advantage of this approach is that it maximizes the vertex fan-out and may therefore yield a shallower graph.

Another approach is to select a subset of A. Let E be a subset of A consisting of all arc labels obtained from keys where no wildcard bits are retrieved (and assigned) and I be a subset of A of all arc labels obtained from keys where at least one wildcard bit is retrieved (and assigned), during arc map computation. Clearly, |A|≤|E|+|I|.

Now let S=E\I, where \ denotes ‘set difference’. Choosing S yields a set of sets of keys {K_{σ}|σ∈S} which is a partition of the set ∪_{σ∈S}K_{σ}, thus achieving zero replication. However, all keys that contain wildcards among the retrieved bits will be used in the recursive construction of the ‘unspecified subgraph’. If there are many such keys, the number of keys in the unspecified subgraph may be almost the same as the number of keys to start with, when constructing the vertex, and the vertex may thus be slightly inefficient. An arc label present in the set S, constructed as described in this section, is referred to as an ‘explicit arc label’. Any other arc label is referred to as ‘implicit arc label’.

Yet another approach, which is a middle-way between the two extremes described above, is to let S=E. By this approach, all arc labels that are ‘explicitly’, e.g., without wildcard bit retrieval and assignment, obtained by arc map computations constitute specified arc labels. Some of the keys that yield ‘implicit’, e.g., involving wildcard retrieval and assignment, arc labels are also treated as specified and will be replicated.

There are several optimization criteria that may be considered when constructing a graph. Examples of such optimization criteria include minimizing the number of branching vertices, minimizing the number non-branching vertices, and minimizing the number of arcs. In the graph memory model arcs correspond to vertices and an efficient representation minimizes the search time by minimizing the number of arcs traversed during search and the graph space (memory) by minimizing the overall number of arcs.

In the simplest possible embodiment, suitable for applications where the keys stored in the graph are fully specified, only specified arcs are required. Let k be the maximum number of bits that can be retrieved during data- and arc map computations. By selecting the k bits that maximizes |A|, the number of arcs, from a given vertex, is maximized and the depth of the graph is minimized. Since the keys are wildcard free each key is only stored in exactly one subgraph of each vertex thus no replication occurs.

In an alternative embodiment, also suitable for applications where the keys stored in the graph are fully specified, both specified- and unspecified arcs are used. In such an embodiment the main reason for using unspecified arcs instead of several specified arcs is to consolidate subsets of keys that are small compared to other subsets of keys. For example, if there are three sets of keys with five keys in each with three corresponding specified arc labels α₁, α₂, α₃, and five single key sets with corresponding arc labels α₄, α₅, α₆, α₇, α₈, the last five single key subsets can be consolidated into one and stored in the subgraph reached via the unspecified arc. In this way, all four subgraphs will contain five keys.

In yet another alternative embodiment, suitable for applications where the keys stored in the graph contains wildcards, only specified- and unspecified arcs are used. In such an embodiment, the set S contains only explicit arc labels and the keys from which these arc labels are obtained are stored in the corresponding subgraphs whereas all keys from which implicit arc labels are obtained are stored in the unspecified subgraph.

In yet another alternative embodiment, suitable for applications where the keys stored in the graph contain wildcards, only specified- and mandatory arcs are used. In such an embodiment, specified arc labels may or may not include implicit arc labels whereas keys with implicit arc labels are stored in the mandatory subgraph. If all specified arcs labels are explicit arc labels no replication occurs and the vertex is optimal, with respect to the chosen method of arc map computation, from a space (memory, storage) perspective.

In yet another alternative embodiment, suitable for applications where the keys stored in the graph contain wildcards, both specified, unspecified, and mandatory arcs are used. In such embodiments, keys with implicit arc labels are preferably stored in the mandatory subgraph to minimize replication whereas some keys with explicit arc labels may be stored in the unspecified subgraph to balance the number of keys between subgraphs.

In an alternative embodiment, suitable for applications where the keys stored in the graph contain wildcards, the set of specified arc labels is a subset of the arc labels that can be obtained from the keys when considering all possible assignments of wildcard bits retrieved from the keys. If, in a vertex produced in such an embodiment, the set of specified arc labels is identical to the set of obtained arc labels a mandatory arc is not required and, consequently, the mandatory subgraph does not exist (or is empty). Otherwise, a mandatory arc is required and all keys producing one or more arc labels not in the set of specified arc labels must be stored in the mandatory subgraph. Otherwise, any arc label missing from the set of specified arc labels is considered either unspecified or mandatory and the key associated with such an arc label is stored in the corresponding unspecified- or mandatory subgraph and any key associated with one or more specified arc labels is replicated and stored in each of the corresponding subgraphs. In such an embodiment, only keys with arc labels that do not match any of the specified arc labels are stored in the unspecified subgraph.

Data and data map computation have been described in the context of vertices where the method is the same independently of how a search arrives at the vertex. In alternative embodiments, targeted for specific applications where a cyclic graph is used, the data map computation method may be associated with the arc leading to the vertex so that different methods are used depending on how the search arrives at the vertex.

Ares and arc map computation have been described in the context of vertices where the method is the same independently of how a search arrives at the vertex. In alternative embodiments, targeted for specific applications where a cyclic graph is used, the arc map computation method may be associated with the arc leading to the vertex so that different methods are used depending on how the search arrives at the vertex.

An important part of the vertex construction of a graph is to is to determine the method of retrieval of bits from keys, ‘bit retrieval, and arc map computation in each vertex. There are four main approaches to bit retrieval: (i) ‘single bit retrieval’ where a single bit is retrieved and its value constitutes a 1-bit arc label, (ii) ‘multiple bit retrieval’ where a number k of adjacent bits are retrieved and their value, interpreted as a non-negative integer, constitutes a k-bit arc label, (iii) ‘scattered bit retrieval’ where a number k of scattered bits are retrieved, and concatenated, and their value, interpreted as a non-negative integer, constitutes a k-bit arc label, and (iv) ‘scattered bit computation’ where an arbitrary number of scattered bits are retrieved and some form of computation (e.g., computation of hash, counting number of 0s, etc.) is performed on the retrieved bits yielding a k-bit non-negative integer that constitute the arc label.

In an embodiment where single bit retrieval is used the arc map computation method only retrieves a single bit yielding 1-bit arc labels. In a vertex where a single bit is retrieved there is no need for unspecified subgraphs and only a 0-arc and a 1-arc is required. A +-arc for keys where the extracted bit is wildcard may also be used to minimize replication at the cost of search performance (space vs. time trade-off).

In another single bit retrieval embodiment, the bit to retrieve in a vertex increases with the distance of the vertex from the root such that bit 0 is retrieved in the root, bit 1 is retrieved in each of the two (or three if there is a mandatory arc) children of the root, and so on.

In an alternative single bit retrieval embodiment where keys are inserted in the graph on-the-fly (e.g., the graph is dynamically updated rather than being built/rebuilt from scratch), a ‘new key’ is inserted by traversing the graph starting from the root, noting that traversal branches, recursively until a non-branching vertex is encountered. The subgraph where the non-branching vertex is the root is referred to as ‘old subgraph’. Then a ‘new subgraph’ is constructed from all keys in the encountered old subgraph and the new key and the old subgraph is replaced by the new subgraph. In such an embodiment, subgraphs may be inefficiently stored due to the order of which keys arrive and needs to be regularly optimized and reconstructed. This is achieved by partial reconstruction of the corresponding subgraphs and described in detail in the context of ‘incremental update’ of graphs.

In yet an alternative embodiment, referred to as a ‘quantum key based single bit retrieval’ embodiment, a quantum key representing the n keys is constructed and the optimal bit to retrieve is selected based on minimizing cost according to a cost function that for a given bit index i compute the cost for selecting that bit from n and qᵢ=(nᵢ₀, nᵢ₁, n_{i*}). Such cost functions typically yield high costs for bit indexes i where n_{i*} is large and the difference between nᵢ₀ and nᵢ₁ is large, and small costs for bit indexes where nᵢ₀≈nᵢ₁ and n_{i*} is small −nᵢ₀=nᵢ₁=n/2 and n_{i*}=0 being the ideal.

In a basic multiple bit retrieval embodiment, the most significant first to bits of the keys are selected in the root vertex, the next tᵢ most significant bits are selected in each vertex being a child of the root, and so on until the last tₜ₋₁ bits are selected in the leaves. The resulting graph from such an embodiment is called t₀, t₁, . . . , tₜ₋₁ ‘variable stride trie’ and is commonly used to perform longest prefix matching (LPM).

In an alternative embodiment, referred to as a ‘quantum key based multiple bit retrieval’ embodiment, a quantum key is constructed and the optimal sequence of bits to retrieve is selected based on minimizing a cost according to a cost function that for a given start bit index ƒ and an end bit index t compute a cost from the number of keys n and q_{ƒ}, q_{ƒ+1}, . . . , qₜ₋₁, qₜ.

The optimization criteria in quantum key based multiple bit retrieval is essentially the same as for quantum key based single bit retrieval in that sequences of bit indices where there are lots of wildcards should be avoided and a balance between the number of keys ending up in each subgraph (noting that 2^{t-ƒ+1} children is possibly required compared to two to three for quantum key based single bit retrieval). The advantage of quantum key based multiple bit retrieval compared to quantum key based single bit retrieval is that a larger number of bits yields more children (subgraphs) which enables a more efficient reduction of matching key candidates in each vertex and thus a shallower graph featuring faster search. However, the drawback is that replication of keys may increase a lot when several bits are inspected especially if the sequence of bit indices is not carefully chosen.

In a preferred quantum key based multiple bit retrieval embodiment the ‘composite cost’, for selecting a ‘sequence’ ƒ . . . t of multiple adjacent bit indices starting with ƒ and ending with t, is computed as follows. First a base β is computed as β=max(N, 2^{ω})+1, where N is the overall maximum number of keys that may be stored in the graph and a is the maximum number of adjacent bits that may be retrieved in a single vertex. Since there is a limit on the number of bits that may be retrieved any sequence where t−ƒ>ω yields an infinite ∞ composite cost. A bit index that has been retrieved in one or more ancestor vertices is said to be ‘checked’, and such bits are considered for repeated retrieval if it improves the overall sequence. Any sequence including a pair of non-checked bit indices i and j such that n_{i*}≠n_{j*} yields composite cost ∞. For any other bit sequence, let n, be the number of wildcard bits in the non-checked bit positions. Any sequence where n_{*}>0 that include one or more checked bits, or where ƒ≠t, yields composite cost ∞. To clarify, for sequences where the keys contain wildcards in the bit positions selected a shorter sequence is preferred over a longer sequence. Furthermore, any sequence where n_{*}=0 that includes a checked bit i such that n_{i*}>0 yields composite cost ∞. Finally, the composite cost is computed as a function of α, β, ƒ, t and the quantum key, where α=2^{Σ}^{_{i=ƒ}}^{^{t}}^{γ}^{ᵢ}, γᵢ=0 if nᵢ₀=0 and nᵢ₁=0, and 1 otherwise, and δ=min(|nᵢ₀−nᵢ₁|, i=ƒ . . . t). Parameters of the cost function are configured to achieve optimal bit selection for the respective target applications.

In an alternative quantum key based multiple bit retrieval embodiment, guaranteed to check each bit only once, the ‘composite cost’, for selecting a ‘sequence’ ƒ . . . t of multiple adjacent bit indices starting with ƒ and ending with t, is computed as follows as described above except that any sequence including a checked bit yields composite cost ∞.

In all quantum key based multiple bit retrieval embodiments the bit sequence with the smallest composite cost is chosen and the set of specified arc labels is computed by retrieval of the bits from the respective keys according to the chosen sequence. Keys are distributed into subsets according to which specified arc label that can be obtained from the respective key and an arc to a subgraph is created for each subset followed by recursively constructing the respective subgraph for each specified arc.

### Search

In general, search refers to the process of starting at a given vertex, which is typically a/the ‘root’ and locating all reachable keys stored in the graph that ‘matches’ a given ‘query key’. By matches we mean that for each specified bit in the query key the corresponding bit in the matching key stored in the graph is either equal or wildcard. For computer networking applications the query key is often fully specified (there are no wildcard bits). However, there are also applications where query keys contain one or more wildcard bits. This is called ‘full multi-match search’.

Graphs where keys are associated with priorities may also support search of the matching key with highest priority, a given number of matching keys with the highest priorities, or all matching keys in order of decreasing priority. Note that this either requires some tie breaker mechanism to be available for matching keys with equal priorities or that priorities are unique.

A weaker form of search is to locate a set of candidate keys, which is a subset of the set of keys stored in the graph, that may match the query key. In this way, the set of candidate keys is reduced in size compared to the original set of keys stored in the graph and the detailed investigation of which of these candidates that are matching the query key can be performed in a second operation using whatever method that is available. This is called ‘partial match search’.

For each vertex visited during search the arc label (if the query key is fully specified) or set of arc labels (if the query key contains wildcards) is retrieved using the bit retrieval method and computed using the arc map computation method specified in the vertex. Search is then performed recursively in each subgraph reachable via the specified arc with a specified arc label equal to any of the arc labels retrieved from the query key. If there are no specified arc labels that matches the arc labels obtained from the query key, search is performed recursively in the unspecified subgraph if such a subgraph is available. Furthermore, search is also performed recursively in the mandatory subgraph if such a subgraph is available. If the vertex visited contains specified data with specified data that matches any of the data labels obtained by computing the data map of the key such matching data is output. If the data labels obtained from the key do not match any specified data label, the unspecified data is output if such data is available in the vertex. In addition, any mandatory data in the vertex is output independently of whether there is a specified data label match or not. If the vertex does not contain any arcs that can be traversed, the search halts.

In one embodiment, suitable for classification of Internet datagrams (or packets), query keys are fully specified, and only specified and unspecified arcs are used (no mandatory arcs). In such an embodiment, a single arc label is obtained from the query key at each node. Such an arc label is either matched against exactly one specified arc label and the search continues in the associated specified subgraph or does not match any of the specified arc labels in which case the search continues in the unspecified subgraph if an arc leading to such a subgraph is available in the vertex. If the arc label from the key does not match any of the specified are labels and no unspecified subgraph is available, the search is terminated after processing any data present in the node as outlined above.

In an alternative embodiment, also suitable classification of Internet datagrams (or packets), query keys are fully specified, and both specified-, unspecified-, and mandatory arcs are used. In such an embodiment, a single arc label is obtained from the query key at each vertex. Such arc labels are either matched against exactly one specified arc label and the search continues in the associated specified subgraph or does not match any of the specified arc labels in which case the search continues in the unspecified subgraph if an arc leading to such a subgraph is present in the vertex. In addition, search is always performed recursively in the mandatory subgraph if such a subgraph is available. If the arc label obtained from the key does not match any of the specified edge values, no unspecified subgraph is available, and no mandatory subgraph is available, the search is terminated after processing any data present in the node as outlined above.

### Updates

Graph construction has been described above from the perspective of construction of graphs from scratch. It has also been mentioned briefly, in the context of single bit retrieval arc and data maps and associated vertex construction, that keys can be inserted on-the fly, while dynamically updating the graph rather than reconstructing it from scratch. This is called an ‘incremental update’ of the graph.

There are two main incremental update operations: ‘insert’ key and ‘delete’ key, both referring to single key operations. Variants of ‘insert’ and ‘delete’ include ‘burst insert’ and ‘burst delete’ for inserting and deleting, respectively, all keys in a set of keys. As a result of an update operation, some part of the graph may need to be maintained or optimized. This is achieved by partial reconstruction, while considering certain metrics recording the state of the graph. Burst updates, insertions as well as deletions, can either be performed as repeated single updates or as a ‘consolidated update’ applied on sets of keys. In both cases, optimization is performed after the burst update is completed. Typically, partial reconstruction does not include partitioning from scratch, as performed during initial partitioning of the keys into subsets and construction of one graph for each subset during a batch build. It may, however, be necessary to move keys between subsets after an update operation. This is achieved in the context of ‘maintenance’ described below.

As mentioned above, partitioning is used to partition the keys into subsets according to some niceness criteria with respect to the other keys in the same subset. The purpose of this is to minimize the amount of replication when constructing the graph for each subset.

The method for ‘insertion’ of a ‘new key’ in a graph is as follows. Insertion of a single key K in an empty subgraph or in a subgraph where an irreducible set of keys is stored (identified by a non-branching root vertex) is achieved by constructing a subgraph as outlined above. Otherwise, in each node encountered, starting with the root vertex, the set of arc values of the new key is computed by using the bit retrieval- and arc map computation method associated with the vertex. For each arc label α present in the set of specified arc labels, of the vertex, insertion is performed recursively in the corresponding α-subgraph. For each β of the remaining arc labels a new β-arc referring an empty subgraph is constructed and the key is recursively inserted in each such empty subgraph. If the embodiment includes mandatory edges, a selection of the remaining arc labels may be skipped by recursively inserting the key in the mandatory subgraph instead.

FIG. 6 shows the graph resulting from inserting the new key *101*011 with data D₅ in the graph shown in FIG. 2. Since bit 5 is wildcard, the new key is replicated in both the 10_{b} and 11_{b} subgraph of the root node. Note also that the new key is replicated in the 10_{b} subgraph since bit 1 is wildcard.

In one embodiment, where partitioning is used to partition the set of keys in subsets and one graph is constructed (and maintained), each subset of keys, and the corresponding graph the keys are stored in, is associated with a quantum key. In such embodiments, the distance between the new key to be inserted and each of the quantum keys is computed and the new key is inserted into the graph associated with the quantum key yielding the shortest distance.

In an alternative embodiment, a ‘replication cost’ for each subset, and corresponding graph, is computed for the new key to be inserted. Replication cost is computed ‘simulating’ an insertion and count how many new vertices and arcs that are required to insert the key in the graph. This is followed by inserting the key into the graph with the lowest replication cost. Note that replication cost computed as described herein is a heuristic since the actual impact of adding a key to an existing graph can only be assessed with certainty by reconstructing the entire graph from scratch.

### Maintenance

As mentioned above, the purpose of graphs is to represent a set of keys efficiently to support fast search of a single best matching key that matches a query key, multiple (e.g., all) keys that matches a query key, or a set of keys that may match the query key without confirming match. The key set is partitioned into subsets, using partitioning, with the purpose of enabling efficient graph construction from the respective subset in the partition. If all graphs are constructed from scratch, the entire knowledge of how keys relate to each other is known from start and it becomes simpler (or at least possible) to obtain efficient partitioning, and to perform efficient selection of bit retrieval and arc map computation selection in each vertex in each graph.

However, when keys arrive and are inserted on the fly there is a higher probability both that mistakes are made during partitioning and, also, that mistakes are made during selection of bit retrieval and arc map computation method in each node. The purpose of maintenance is to reduce the impact of—and correct mistakes done during incremental updates due to incomplete information.

‘Partition maintenance’ is achieved by storing all keys in each subset in partition maintenance queue. One unit of partition maintenance work is constituted by selecting the key next in turn from the queue and checking the distance between the key and the quantum key of each subset in the partition. If the smallest distance obtained is between the key and the current subset where the key is stored, it is simply inserted at the back of the queue and the unit of maintenance work is completed. Otherwise, it is inserted into the graph of the subset where the distance is shortest and then removed from the current subset and corresponding graph. When inserted into the new subset it is also inserted in the back of the partition maintenance queue of that subset.

The amount of partition maintenance work to be done in relation to the number of incremental updates can be configurable. For example, in a basic embodiment, one piece of maintenance work in a subset is done every time an update operation, e.g., graph insert of graph delete, is performed in that subset. In such embodiments, it is still possible that several pieces of maintenance work are performed due to a chain reaction of keys being moved between subsets.

In an alternative embodiment, a global partition maintenance task queue is used and instead of executing indirect partition maintenance work (caused by chain reactions) directly, pieces of work are enqueued in the global partition maintenance queue. In such embodiments, a piece of maintenance work corresponds to removing the first task from the queue and executing it, possibly resulting in that an additional task is created and inserted into the partition maintenance task queue.

In yet another alternative embodiment, a certain number of pieces of partition maintenance work is performed after each update operation.

In yet another alternative embodiment, one piece of partition maintenance work is performed after a certain number of update operations.

In yet another alternative embodiment, the amount of partition maintenance work performed after an update operation is determined by one or more thresholds, for example one threshold for each subset and/or one threshold for the entire partition maintenance task queue, such that sufficiently many partition maintenance tasks are executed to ensure that the number of remaining tasks is kept below the respective thresholds.

Maintenance work is also performed in individual graphs. This is called ‘graph maintenance’.

In each vertex of each graph statistics may be recorded, or made available by other means, to enable analysis of the efficiency of the subgraph rooted at said vertex. Such statistics include: ‘density’ which is the number of unique keys stored in the subgraph, rooted at the current vertex, ‘weight’ which is the total number of keys stored in the subgraph (thus, the relationship between weight and density constitutes a measurement of the amount of replication in a subgraph), rooted at the current verted, including replication, ‘height’ which is the longest path from the current vertex to a vertex without arcs, ‘depth’ which is the number of ancestor vertices of the current vertex, ‘degree’ which is the size of S, the number of specified subgraphs of the current vertex.

In a basic embodiment, statistics in each vertex visited during a graph update operation are analyzed. If the statistics in such a vertex suggest that the subgraph is inefficiently represented, a complete reconstruction may be performed. Should several subgraphs, containing the dominating part of the keys, of an ancestor vertex be selected for complete reconstruction but the ancestor vertex is not, it is sometimes more efficient to reconstruct the subgraph rooted at the ancestor vertex.

In an alternative embodiment, the analysis of statistics is performed by measuring the absolute replication given by subtracting density from weight. If the absolute replication is large, it is an indication that the subgraph rooted at the vertex is in bad shape.

In yet another alternative embodiment, the analysis of statistics is performed by measuring the relative replication given by dividing weight by density. If the relative replication is large, it is an indication that the subtree rooted at the vertex is in bad shape.

In yet another alternative embodiment, the analysis of statistics is performed by measuring the degree of the current vertex compared to some expected degree, and if it is considerably lower it may suggest that the subgraph rooted at the current vertex is in bad shape.

In yet another embodiment, the height of the subgraph is compared to the logarithm with base being the expected degree and if the height is considerably larger it may suggest that the subgraph rooted at the current vertex is in bad shape.

Note that these different metrics obtained from the statistics stored in a vertex are not at all independent. Replication, for example, clearly has a negative impact on height.

In yet another embodiment, different metrics are combined to obtain a holistic measure of the shape of the current subgraph.

### Example Implementation Environments

Generally, the algorithms and methods described and illustrated above may be implemented in software, programmable hardware, or a combination of the two. For example, in some embodiments the algorithms may be implemented via software instructions (code) that is executed on a processor, central processing unit (CPU) or the like. The processor/CPU may be a multi-core processor with multiple processor cores. The workload may be portioned into multiple threads or the like that may be executed on one or more of the processor cores. Apparatus that may be used for executing such software include but are not limited to computing devices, such as servers, appliances, infrastructure processing units (IPUs), data processing units (DPUs), Edge Processing Units (EPUs), network forwarding elements (e.g., network switch/router), and others.

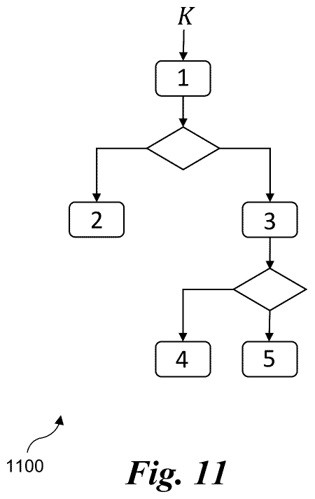

FIG. 12 illustrates an example computing system. System 1200 is an interfaced system and includes a plurality of processors or cores including a first processor 1270 and a second processor 1280 coupled via an interface 1250 such as a point-to-point (P-P) interconnect, a fabric, and/or bus. In some examples, the first processor 1270 and the second processor 1280 are homogeneous. In some examples, first processor 1270 and the second processor 1280 are heterogenous. Though the example system 1200 is shown to have two processors, the system may have three or more processors, or may be a single processor system. In some examples, the computing system is a system on a chip (SoC).

Processors 1270 and 1280 are shown including integrated memory controller (IMC) circuitry 1272 and 1282, respectively. Processor 1270 also includes interface circuits 1276 and 1278; similarly, second processor 1280 includes interface circuits 1286 and 1288. Processors 1270, 1280 may exchange information via the interface 1250 using interface circuits 1278, 1288. IMCs 1272 and 1282 couple the processors 1270, 1280 to respective memories, namely a memory 1232 and a memory 1234, which may be portions of main memory locally attached to the respective processors.

Processors 1270, 1280 may exchange information with a network interface (NW I/F) 1290 via individual interfaces 1252, 1254 using interface circuits 1276, 1294, 1286, 1298. The network interface 1290 (e.g., one or more of an interconnect, bus, and/or fabric, and in some examples is a chipset) may optionally exchange information with a coprocessor 1238 via an interface circuit 1292. In some examples, the coprocessor 1238 is a special-purpose processor, such as, for example, a high-throughput processor, a network or communication processor, compression engine, graphics processor, general purpose graphics processing unit (GPGPU), neural-network processing unit (NPU), embedded processor, or the like.

Generally, in addition to processors and CPUs, the teaching and principles disclosed herein may be applied to Other Processing Units (collectively termed XPUs) including one or more of Graphic Processor Units (GPUs) or General Purpose GPUs (GP-GPUs), Tensor Processing Units (TPUs), Data Processing Units (DPUs), Infrastructure Processing Units (IPUs), Edge Processing Units (EPU), Artificial Intelligence (AI) processors or AI inference units and/or other accelerators, FPGAs and/or other programmable logic (used for compute purposes), etc. While some of the diagrams herein show the use of CPUs and/or processors, this is merely exemplary and non-limiting. Generally, any type of XPU may be used in place of a CPU or processor in the illustrated embodiments. Moreover, as used in the following claims, the term “processor” is used to generically cover CPUs and various forms of XPUs.

A shared cache (not shown) may be included in either processor 1270, 1280 or outside of both processors, yet connected with the processors via an interface such as P-P interconnect, such that either or both processors' local cache information may be stored in the shared cache if a processor is placed into a low power mode.

Network interface 1290 may be coupled to a first interface 1216 via interface circuit 1296. In some examples, first interface 1216 may be an interface such as a Peripheral Component Interconnect (PCI) interconnect, a PCI Express interconnect or another I/O interconnect, such as but not limited to COMPUTE EXPRESS LINK™ (CXL). In some examples, first interface 1216 is coupled to a power control unit (PCU) 1217, which may include circuitry, software, and/or firmware to perform power management operations with regard to the processors 1270, 1280 and/or coprocessor 1238. PCU 1217 provides control information to a voltage regulator (not shown) to cause the voltage regulator to generate the appropriate regulated voltage. PCU 1217 also provides control information to control the operating voltage generated. In various examples, PCU 1217 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 1217 is illustrated as being present as logic separate from the processor 1270 and/or processor 1280. In other cases, PCU 1217 may execute on a given one or more of cores (not shown) of processor 1270 or 1280. In some cases, PCU 1217 may be implemented as a microcontroller (dedicated or general-purpose) or other control logic configured to execute its own dedicated power management code, sometimes referred to as P-code. In yet other examples, power management operations to be performed by PCU 1217 may be implemented externally to a processor, such as by way of a separate power management integrated circuit (PMIC) or another component external to the processor. In yet other examples, power management operations to be performed by PCU 1217 may be implemented within BIOS or other system software.

Various I/O devices 1214 may be coupled to first interface 1216, along with a bus bridge 1218 which couples first interface 1216 to a second interface 1220. In some examples, one or more additional processor(s) 1215, such as coprocessors, high throughput many integrated core (MIC) processors, GPGPUs, accelerators (such as graphics accelerators, digital signal processing (DSP) units, and cryptographic accelerator units), FPGAs, XPUs, or any other processor, are coupled to first interface 1216. In some examples, second interface 1220 may be a low pin count (LPC) interface. Various devices may be coupled to second interface 1220 including, for example, a keyboard and/or mouse 1222, communication devices 1227 and storage circuitry 1228. Storage circuitry 1228 may be one or more non-transitory machine-readable storage media, such as a disk drive, Flash drive, SSD, or other mass storage device which may include instructions/code and data 1230. Further, an audio I/O 1224 may be coupled to second interface 1220. Note that other architectures than the point-to-point architecture described above are possible. For example, instead of the point-to-point architecture, a system such as system 1200 may implement a multi-drop interface or other such architecture.

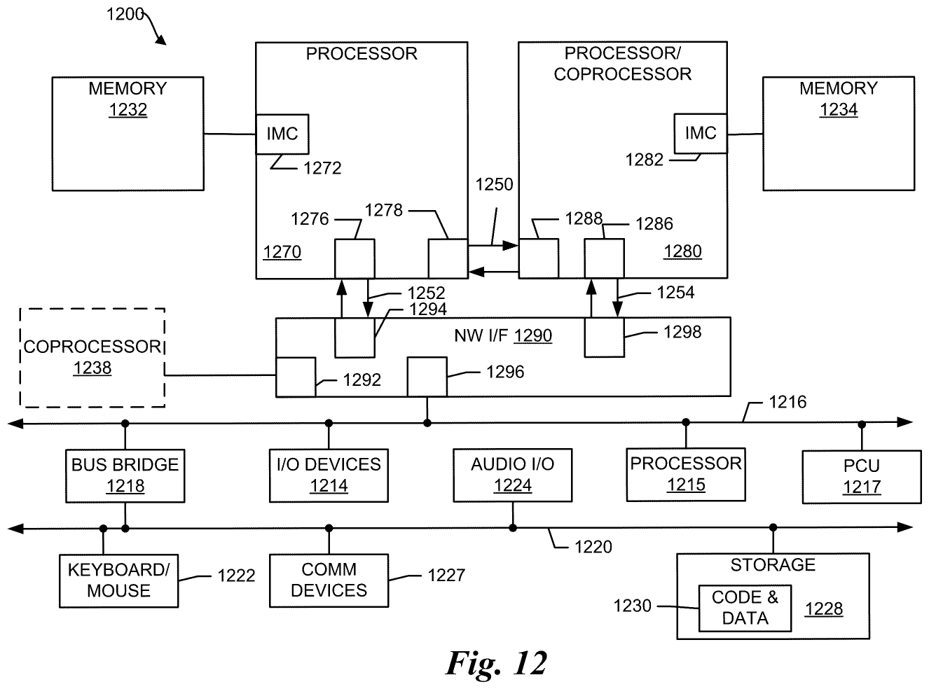

FIG. 13 shows one embodiment of IPU 1300 comprising a PCIe card including a circuit board 1302 having a PCIe edge connector to which various integrated circuit (IC) chips and modules are mounted. The IC chips and modules include an FPGA 1304, a CPU/SOC 1306, a pair of QSFP (Quad Small Form factor Pluggable) modules 1308 and 1310, memory (e.g., DDR4 or DDR5 DRAM) chips 1312 and 1314, and non-volatile memory 1316 used for local persistent storage. FPGA 1304 includes a PCIe interface (not shown) connected to a PCIe edge connector 1318 via a PCIe interconnect 1320 which in this example is 16 lanes. The various functions and logic in the embodiments described and illustrated herein may be implemented by programmed logic in FPGA 1304 and/or execution of software on CPU/SOC 1306. FPGA 1304 may include logic that is pre-programmed (e.g., by a manufacturing) and/or logic that is programmed in the field (e.g., using FPGA bitstreams and the like). For example, logic in FPGA 1304 may be programmed by a host CPU for a platform in which IPU 1300 is installed. IPU 1300 may also include other interfaces (not shown) that may be used to program logic in FPGA 1304. In place of QSFP modules 1308, wired network modules may be provided, such as wired Ethernet modules (not shown).

CPU/SOC 1306 employs an SoC including multiple processor cores. Various CPU/processor architectures may be used, including but not limited to x86, ARM®, and RISC architectures. In one non-limiting example, CPU/SOC 1306 comprises an Intel® Xeon®-D processor. Software executed on the processor cores may be loaded into memory 1314, either from a storage device (not shown), for a host, or received over a network coupled to QSFP module 1308 or QSFP module 1310.

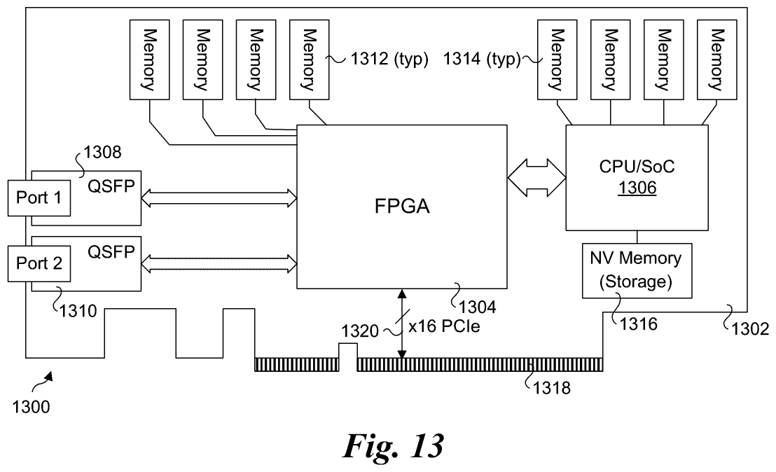

FIG. 14 shows a SmartNIC 1400 comprising a PCIe card including a circuit board 1402 having a PCIe edge connector and to which various integrated circuit (IC) chips and components are mounted, including optical modules 1404 and 1406. The IC chips include an SmartNIC chip 1408, an embedded processor 1410 and memory chips 1416 and 1418. SmartNIC chip 1408 is a multi-port Ethernet NIC that is configured to perform various Ethernet NIC functions, as is known in the art. In some embodiments, SmartNIC chip 1408 is an FPGA and/or includes FPGA circuitry.

Generally, SmartNIC chip 1408 may include embedded logic for performing various packet processing operations, such as but not limited to packet classification, flow control, RDMA (Remote Direct Memory Access) operations, an Access Gateway Function (AGF), Virtual Network Functions (VNFs), a User Plane Function (UPF), and other functions. In addition—various functionality may be implemented by programming SmartNIC chip 1408, via pre-programmed logic in SmartNIC chip 1408, via execution of firmware/software on embedded processor 1410, or a combination of the foregoing. The various algorithms and logic in the embodiments described and illustrated herein may be implemented by programmed logic in SmartNIC chip 1408 or and/or execution of software on embedded processor 1410.

Generally, an IPU and a DPU are similar, whereas the term IPU is used by some vendors and DPU is used by others. As with IPU/DPU cards, the various functions and logic in the embodiments described and illustrated herein may be implemented by programmed logic in an FPGA on the SmartNIC and/or execution of software on CPU or processor on the SmartNIC. In addition to the blocks shown, an IPU or SmartNIC may have additional circuitry, such as one or more embedded ASICs that are preprogrammed to perform one or more functions related to packet processing and Tx descriptor processing operations.

An EPU may also have similar compute and memory resources as an IPU or DPU where, as its name implements, an EPU is generally implemented at an edge of a distributed environment, such as a cloud edge, data center edge, etc. IPUs, DPUs, and EPUs may be implemented using various configurations, such as an expansion card in a server, a card in a network appliance (e.g., edge appliance), or similar processing and memory resources may be implemented on a system board.

Recently, tile-based SoC and System on Package (SoP) architectures have been introduced. Under such architectures, functionality that might be implemented via an expansion card or the like is implemented in a “tile” of “die” that is part of the SoC or SoP. In some embodiments the SoC/SoP includes an on-package Accelerator Complex (AC) that employs a combination of a new IP (Intellectual Property) interface tile die and disaggregated IP tiles, which may be integrated on an IP interface tile or may comprise separate dies. In one embodiment, the interface tile connects to the System on Chip (SoC) compute CPU tile using the same Die-to-Die (D2D) interfaces and protocol as an existing CPU IO die. This enables high bandwidth connections into the CPU compute complex.

The AC provides high bandwidth D2D interfaces to connect independent accelerator and IO tiles, e.g., Flow Classification, Ethernet IO, encryption/decryption accelerators, compression/decompression accelerators, AI or media accelerators, etc. Such disaggregation enables these tiles to be developed in a relatively unconstrained manner, allowing them to scale in area to meet the increasing performance needs of the Beyond 5G (B5G) roadmap. Additionally, these IPs may connect using protocols such as CXL (Compute Express Link), Universal Chiplet Interconnect Express (UCIe), or Advanced eXtensible Interface (AXI) that may provide the ability to scale bandwidth for memory access beyond PCIe specified limits for devices. Leveraging industry standard on-package IO for these D2D interfaces, e.g., AIB, allows integration of third-party IPs in these SoCs. On-package integration in this manner of such IPs provides a much lower latency and power efficient data movement as compared to discrete devices connected over short reach PCIe or other SERDES (serializer/deserializer) interfaces. Additionally, the disaggregated IP tiles can be constructed in any process based on cost or any other considerations.

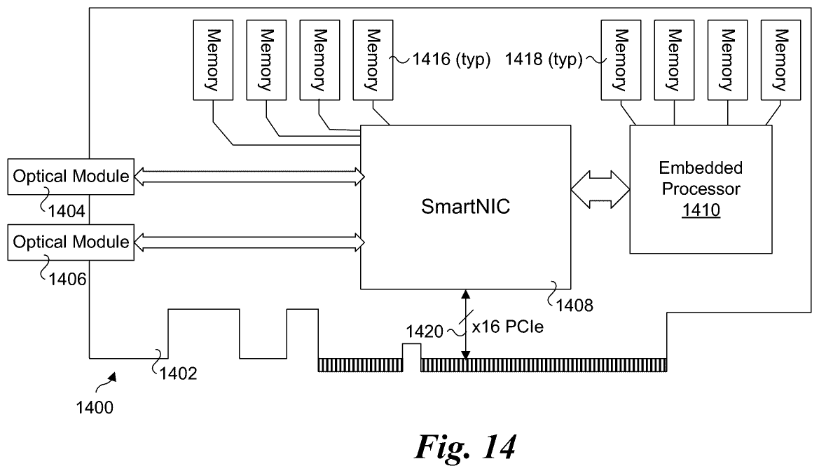

FIG. 15 shows an exemplary AC 1508 integrated on a multi-die package 1500, which includes a CPU 1502 coupled to an IO subsystem 1504 via IO interfaces 1506. Generally, IO subsystem 1504 and IO interfaces 1506 are illustrative of conventional IO components and interfaces that are known in the art and outside the scope of this disclosure.

AC 1508 includes an IP interface tile 1510 having a CPU interface (I/F) 1512 coupled to CPU 1502 via a D2D interface 1514. Multiple components are coupled to CPU interface 1512 via an interconnect structure 1514 including a shared memory controller 1517, an interface controller 1518, a data mover 1520, and IP interfaces 1522. IP interfaces 1522 represent IP interfaces that are coupled to respective IP tiles, including an Ethernet IP tile 1524, a flow classification IP tile 1526, an AI (Artificial Intelligence), media and third-party IPs tile 1528, and a CXL/PCIe (Compute Express Link/Peripheral Component Interconnect Express) root port tile 1530 via respective interconnects 1532, 1534, 1536, and 1538. In some embodiments, interconnects 1532, 1534, 1536, and 1538 comprise on-package die-to-die interfaces or chiplet-to-chiplet interconnects such as UCIe.

As shown on the left-hand side of FIG. 15, shared memory controller 1517 may include scratchpad memory 1540. It may also include one or more LPDDR/DDR/GDDR memory interfaces 1542 to which external memory devices would be coupled, such as depicted by ECC RDIMMs 1544. Optionally, shared memory controller 1517 may be coupled to stacked High-bandwidth Memory (HBM) comprising on package memory. In one embodiment the SMC subsystem memory appends to the main memory as a distinct NUMA (Non-Uniform Memory Access) domain.

In an alternative embodiment (not shown), scratchpad memory 1540 is implemented on IP interface tile 1510 is used for transient data such as used in RAN (Radio Access Network) pipeline processing, edge network flow processing, media processing, and processing of types of data. This memory is accessible by both the IO and accelerators on the AC as well as the SoC CPU(s). Dis-aggregating and dedicating memory for this purpose provides a multitude of benefits that are advantageous for meeting the ongoing demands of the B5G RAN pipe. When implemented on IP interface tile 1510 the scratchpad memory provides a low and deterministic latency when compared to the CPU main memory system, an important variable that needs be to addressed to ensure IPs can meet real-time latency requirements as well as sustain more than 10× increase in memory bandwidth demand expected in future applications, such as B5G. Since the IPs connected to the AC access this local memory, such accesses no longer use the CPU interconnect and external memory allowing the CPU-to-memory bandwidth to be reserved for CPU compute operations.

In one embodiment, the scratchpad memory is software-managed and not hardware coherent to avoid the costs and overheads of coherency management. Optionally, the AC may implement memory coherency for a portion or all memory usage.

Generally, interface controller 1518 comprises a small core, microcontroller, or other processing element that can be used to offload the management of RAN pipeline control tasks such as scheduling hardware accelerators and setting up the data movement actions for chaining of tasks across accelerators. Offloading these operations improves the efficiency of the CPU by unburdening the CPU of such control management actions and allowing focus on their own compute tasks. The use of local management is also more efficient and reduces pipeline jitter.

Data mover 1520 comprises an IP block, such as but not limited to a Data Streaming Accelerator (DSA) that provides software with a standard interface for efficient data movement between the various accelerators and IO IPs as well as host application domains. This reduces the overheads of relying on cores or data movement engines on other chiplets or dielets to move data between IPs and/or the scratchpad memory 1516 on IP interface tile 1510.

Multi-die package 1500 further shows an external CXL device 1548 and an External PCIe device 1550 connected to CXL/PCIe root port tile 1530. In addition to being implemented as a separate die/tile, in some embodiments a CXL and/or a PCI root port may be integrated on IP interface tile 1510. This will enable external accelerators and IO devices to utilize the components of this on-package AC and optimizes the data flow.

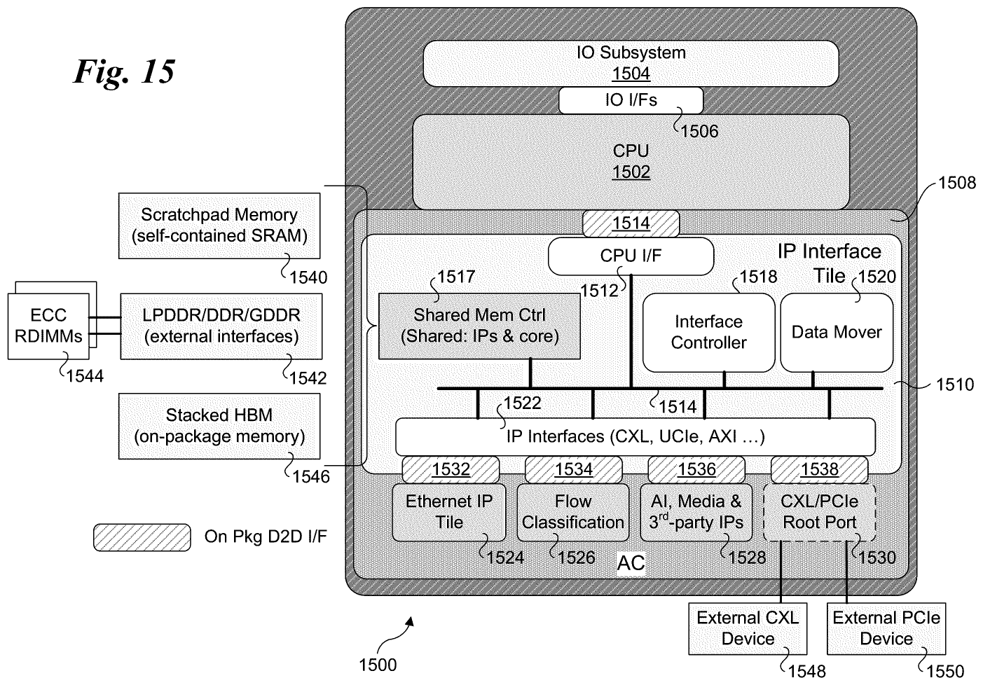

FIG. 16 shows a multi-die package 1600 including a CPU compute block 1602 coupled to AC 1508 via a CPU UFI (Ultra Path Interconnect) interface 1512 and associated UPI interconnect 1616. CPU compute block 1602 include multiple cores 1608 coupled to an LLC (Last-Level Cache) 1610 and an IMC 1612 via an interconnect structure 1614. Each of cores 1608 has associated Level 1 (L1) and Level 2 (L2) caches (not separately shown). IMC 1612 is configured to provide Read/Write access to a memory 1606.

The algorithms and methods described herein may be implemented in multiple ways on multi-die package 1600. For example, a pure software implementation can be implemented by executing software (code/instructions) on one or more of cores 1608. A pure hardware implementation may implement one or more functions employing the algorithms/method on an accelerator die, such as flow classification die 1526. For example, such accelerator dies may comprise one or more FPGAs, ASICs, and/or other types of programmable logic. Under a split software/hardware approach, a portion of the operations for implementing the algorithms may be facilitated by execution of instructions on one or more cores 1608, while the workload for implementing other aspects of the algorithms may be facilitated by an accelerator die.

### Exemplary Use Cases

The principles and techniques disclosed herein generally may be applied to any application that performs ternary key matching at large scales. For instance, consider packet classification. A network forwarding element (e.g., switch/router) or network edge appliance may need to support hundreds of thousands or even millions of flows. Each flow can be identified by information contained in the packets using an m-tuple key, where a tuple is a header field and m≥1. Depending on the implementation, flow classification may require a single tuple (such as an IP destination address for a forwarding application that employs longest prefix match (LPM) or may employ multiple tuples (such as a 5-tuple match). Additional non-limiting example uses include traffic policing and filtering in gateways and other appliances (e.g., action control list (ACL) implementations), and deep packet inspection for security applications.

Other non-limiting examples of use cases include Bioinformatics (e.g., DNA sequencing, etc.), Artificial Intelligence (AI), and machine learning. The techniques and principles may also be applied to searching large datasets that use ternary indexing and for building ternary search trees that may be used for a variety of applications.

Graph Partitioning Vs. TCAM

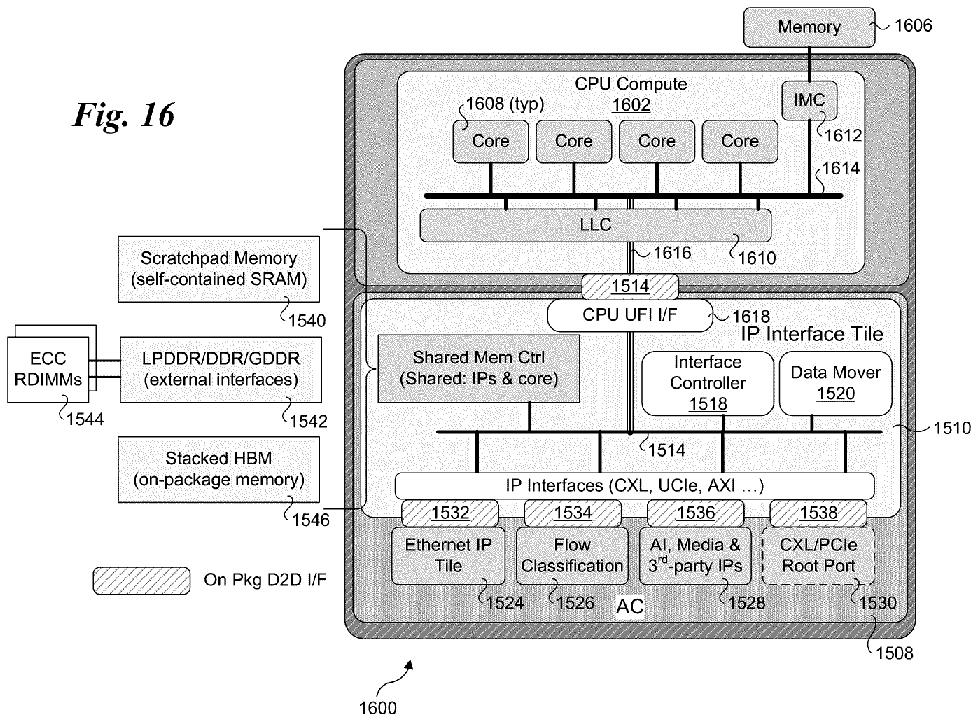

The graph partitioning embodiments disclosed herein provide significant advantages when compared with using a TCAM for large-scale applications such as flow classification, traffic policing and filtering, deep packet inspection, etc. For example, FIG. 17 shows a graph illustrating rule capacity and rule complexity parameters for graph partitioning and a state-of-the-art TCAM. With respect to rule complexity, the least complex rule set consists of 100% specified rules (binary bit strings) and the most complex rule set consists of arbitrary ternary bit strings where the complexity increases if a bit is wildcard with higher probability, and complexity also increases the less variation between 0's and 1's among the specified bits. A TCAM can handle any level of complexity since it applies a brute force approach that is insensitive to the rule structure. In FIG. 17, the rule complexity for graph portioning is based on a small number of sub-graphs for comparison purposes. Greater rule complexity can be handled with additional sub-graphs, which may result in an increase in power consumption (e.g., proportional to an increase in the number of engines; however, the graph partitioning approach will still achieve a better tradeoff between capacity, complexity, and power consumption than TCAMs.

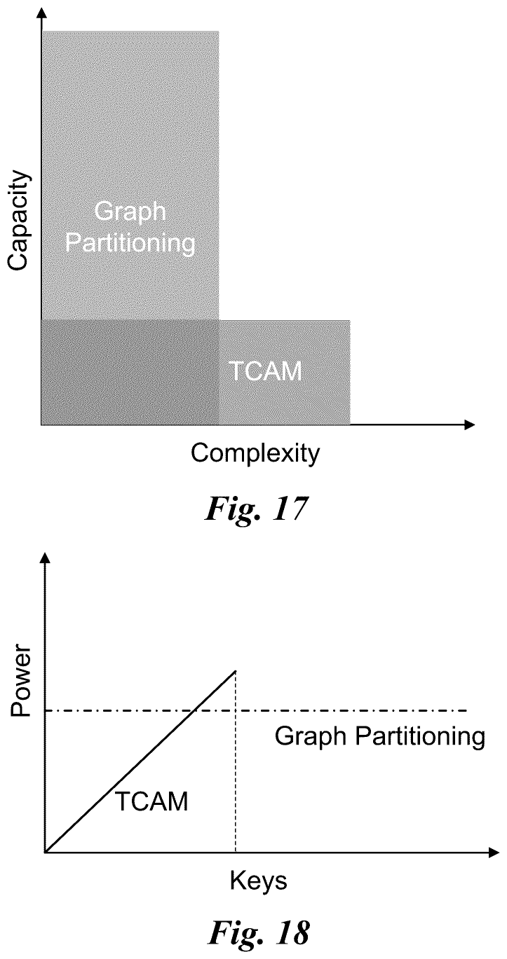

FIG. 18 shows a graph comparing power consumption vs. the number of keys for graph partitioning and a TCAM. As shown, the power consumed by a TCAM is proportional to the number of keys that are to be supported. This is because to support more keys, the size of the TCAM must be proportionally increased and the amount of computation, and thus power consumption, of a TCAM is proportional to the size. Under the graph portioning scheme, the power consumption is substantially fixed for any number of keys as a factor of the number of engines that are used in parallel. For instance, consider a software-based implementation where multiple engines are implemented in parallel via execution of instructions (e.g., threads) on one or more processor cores. The power “cost” of executing the instructions is fixed regardless of the number of keys (the same software code can be used to scale the application to support any number of keys). While there also is power consumed by memory and the processor/CPU caches, that power is likewise substantially fixed (and is relatively small when compared with a TCAM supporting the same number of rules).

In an accelerator use context, a similar result is observed. Under this context, the engines are implemented via one or more hardware-based accelerators, such as using programmed logic in hardware (e.g., an FPGA or ASIC). The power consumption of the accelerator(s)/engines remains substantially fixed regardless of the number of keys that the implementation needs to support.

While various embodiments described herein use the term System-on-a-Chip or System-on-Chip (“SoC”) to describe a device or system having a processor and associated circuitry (e.g., Input/Output (“I/O”) circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., Input/Output (“I/O”) circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems, the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).

As used herein, an “engine” is some means for performing one or more of the operations described and/or illustrated above. Generally, an engine may be implemented in software (e.g., instructions executed on a processing element such as a processor core), in hardware (e.g., logic implemented in one or more of a FPGA, ASIC, or other programmable logic device), or a combination of software and hardware. In one aspect of a software-based implementation, respective sets of instructions are executed on respective cores in a multi-core CPU/processor/SoC. The instructions in a set of instructions may be implemented as one or more threads or processes. In some hardware-based embodiments, each engine is implemented as a respective block of logic (or associative blocks of logic).

While some of the diagrams show numbered operations, the use of numbers is for ease of explanation and does not imply the operations must be performed in the numbered order, although they may be performed in the numbered order is some embodiments. In other embodiments, the order of the operations may be changed. Additionally, in some embodiments, multiple operations may be performed in parallel (concurrently) or substantially concurrently.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

As discussed above, various aspects of the embodiments herein may be facilitated by corresponding software and/or firmware components and applications, such as software and/or firmware executed by an embedded processor or the like. Thus, embodiments of this invention may be used as or to support a software program, software modules, firmware, and/or distributed software executed upon some form of processor, processing core or embedded logic a virtual machine running on a processor or core or otherwise implemented or realized upon or within a non-transitory computer-readable or machine-readable storage medium. A non-transitory computer-readable or machine-readable storage medium includes any mechanism for storing or transmitting information in a form readable by a machine (e.g., a computer). For example, a non-transitory computer-readable or machine-readable storage medium includes any mechanism that provides (e.g., stores and/or transmits) information in a form accessible by a computer or computing machine (e.g., computing device, electronic system, etc.), such as recordable/non-recordable media (e.g., read only memory (ROM), random access memory (RAM), magnetic disk storage media, optical storage media, flash memory devices, etc.). The content may be directly executable (“object” or “executable” form), source code, or difference code (“delta” or “patch” code). A non-transitory computer-readable or machine-readable storage medium may also include a storage or database from which content can be downloaded. The non-transitory computer-readable or machine-readable storage medium may also include a device or product having content stored thereon at a time of sale or delivery. Thus, delivering a device with stored content, or offering content for download over a communication medium may be understood as providing an article of manufacture comprising a non-transitory computer-readable or machine-readable storage medium with such content described herein.

The operations and functions performed by various components described herein may be implemented by software running on a processing element, via embedded hardware or the like, or any combination of hardware and software. Such components may be implemented as software modules, hardware modules, special-purpose hardware (e.g., application specific hardware, ASICs, DSPs, etc.), embedded controllers, hardwired circuitry, hardware logic, etc. Software content (e.g., data, instructions, configuration information, etc.) may be provided via an article of manufacture including non-transitory computer-readable or machine-readable storage medium, which provides content that represents instructions that can be executed. The content may result in a computer performing various functions/operations described herein.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A graph-based method for partitioning a set of ternary keys having one or more wildcards, comprising:
analyzing patterns of the set of ternary keys;
storing ternary keys with a same pattern in a same subset; and
when there are more patterns than a target number of subgraphs,
repeatedly merging patterns until the number of merged patterns matches the target number of subgraphs.

2. The method of claim 1, wherein the patterns include uncompressed patterns and compressed patterns, wherein storing ternary keys with the same pattern in a same subset comprises:
storing ternary keys with a same uncompressed pattern in a same subset; and
storing ternary keys with a same compressed pattern in a same subset.

3. The method of claim 1, wherein merging patterns comprises:
calculating merge costs for candidate patterns to be merged on a pairwise bases, and
merging candidate patterns with a minimum merge cost.

4. The method of claim 3, wherein the merge cost comprises a cost function applied on quantum keys of respective candidate patterns.

5. The method of claim 1, further comprising:
constructing a graph comprising a plurality of subgraphs as compressed M-trie nodes using dynamic programming to determine which bits to inspect in the nodes to yield subgraphs having minimum depth and size.

6. The method of claim 1, further comprising:
generating table entries having ternary keys corresponding to the ternary keys in a final set of merged patterns of ternary keys; and
partitioning the table entries into a plurality of sub-tables, each sub-table associated with a respective sub-graph.

7. The method of claim 6, wherein the query key is derived from one or more fields in a packet header.

8. The method of claim 7, wherein the method supports use 10,000,000 or more packet processing rules.

9. The method of claim 6, further comprising performing a ternary match of a query key by employing a respective engine for each of the plurality of sub-tables to search the plurality of sub-tables for a ternary match of the query key in parallel.

10. The method of claim 9, wherein the respective engines are implemented via execution of respective threads of instructions on a processor.

11. A non-transitory machine-readable medium having instructions stored thereon configured to be executed on one or more processing elements in a computing apparatus, wherein execution of the instructions on the one or more processing elements enables the computing apparatus to partition a set of ternary keys having one or more wildcards by:
creating compressed patterns for a portion of the set of ternary keys;
analyzing uncompressed and compressed patterns of the set of ternary keys;
storing ternary keys with a same uncompressed pattern or compressed pattern in a same subset; and
when there are more patterns than a target number of subgraphs,
repeatedly merging patterns until the number of merged patterns matches the target number of subgraphs.

12. The non-transitory machine-readable medium of claim 1, wherein merging patterns comprises:
calculating merge costs for candidate patterns to be merged on a pairwise bases, and
merging candidate patterns with a minimum merge cost.

13. The non-transitory machine-readable medium of claim 12, wherein the merge cost comprises a cost function applied on quantum keys of respective candidate patterns.

14. The non-transitory machine-readable medium of claim 11, wherein execution of the instructions further enables to computing apparatus to construct a graph comprising a plurality of subgraphs as compressed M-trie nodes using dynamic programming to determine which bits to inspect in the nodes to yield subgraphs having minimum depth and size.

15. The non-transitory machine-readable medium of claim 11, wherein execution of the instructions further enables to computing apparatus to:
generate table entries having ternary keys corresponding to the ternary keys in a final set of merged patterns of ternary keys;
partition the table entries into a plurality of sub-tables, each sub-table associated with a respective sub-graph; and
use the table entries to perform a ternary match of a query key.

16. An apparatus comprising means for partitioning a set of ternary keys having one or more wildcards by:
creating compressed patterns for a portion of the set of ternary keys;
analyzing uncompressed and compressed patterns of the set of ternary keys;
storing ternary keys with a same uncompressed pattern or compressed pattern in a same subset; and
when there are more patterns than a target number of subgraphs,
repeatedly merging patterns until the number of merged patterns matches the target number of subgraphs.

17. The apparatus of claim 16, wherein the means for partitioning the set of ternary keys having one or more wildcards comprises one or more processing elements coupled to memory and instructions configured to be executed on the one or more processing elements.

18. The apparatus of claim 16, wherein the means for partitioning the set of ternary keys having one or more wildcards comprises one or more programmable or preprogrammed logic components comprising one or more of a Field Programmable Gate Array (FPGA), and Application Specific Integrated Circuit (ASIC), and a programmable logic device.

19. The apparatus of claim 18, wherein the apparatus comprises an infrastructure processing unit (IPU), a data processing unit (DPU), or an edge processing unit (EPU).

20. The apparatus of claim 16, wherein means for partitioning the set of ternary keys having one or more wildcards comprises:
one or more processing elements coupled to memory and instructions configured to be executed on the one or more processing elements; and
one or more programmable or preprogrammed logic components comprising one or more of a Field Programmable Gate Array (FPGA), and Application Specific Integrated Circuit (ASIC), and a programmable logic device.
